(19) United States
(12) Patent Application Publication
(10) Pub. No.: US 2026/0180488 A1
(43) Pub. Date: Jun. 25, 2026

(54) SOLAR PHOTOVOLTAIC-POWERED, SELF-CLEANING THERMOELECTRIC SYSTEM FOR NET-ZERO COOLING (SPVTE-C) SYSTEM

(71) Applicant: KING FAHD UNIVERSITY OF PETROLEUM AND MINERALS, Dhahran (SA)

(72) Inventor: Kashif IRSHAD, Dhahran (SA)

(73) Assignee: KING FAHD UNIVERSITY OF PETROLEUM AND MINERALS, Dhahran (SA)

(21) Appl. No.: 19/005,907

(22) Filed: Dec. 30, 2024

(30) Foreign Application Priority Data
Dec. 24, 2024 (SA) 1020247370

(51) Int. Cl. H02S 10/30; H02S 10/20; H02S 10/40; H02S 30/20; H02S 40/10; H02S 40/22; H02S 40/32; H02S 40/42

(52) U.S. Cl. CPC H02S 10/30; H02S 10/20; H02S 10/40; H02S 30/20; H02S 40/10; H02S 40/22; H02S 40/32; H02S 40/425

(57) ABSTRACT

A solar photovoltaic-powered thermoelectric system and a method for using thereof to cool air are described. The solar photovoltaic-powered thermoelectric system includes a cabinet with a plurality of intake air fans and outtake cooling fans, and a plurality of thermoelectric modules. A sliding mechanism is connected to the exterior of the cabinet and supports a fixed bifacial photovoltaic panel and first and second sliding bifacial photovoltaic panels. An inverter generates a DC current from the power generated by the photovoltaic panels. A microcontroller actuates the sliding mechanism to position the photovoltaic panels to receive maximum solar radiation, provides the DC current to the thermoelectric modules, and actuates the intake and outtake fans to draw ambient air towards a heat sink and expel cooled air through an air duct. The solar photovoltaic-powered thermoelectric system provides efficient and sustainable cooling by utilizing solar energy and thermoelectric modules.

### CROSS-REFERENCE TO RELATED APPLICATION

The present disclosure claims the benefit of Saudi patent application Ser. No. 1020247370, filed on Dec. 24, 2024, with the Saudi Authority for Intellectual Property Office, which is incorporated herein by reference in its entirety.

### STATEMENT OF ACKNOWLEDGEMENT

Support provided by the King Fahd University of Petroleum and Minerals (KFUPM), Riyadh, Saudi Arabia through Project No. CREP 2522 is gratefully acknowledged.

### BACKGROUND

### Technical Field

The present disclosure is directed to cooling systems, and more particularly to a solar-powered thermoelectric cooling system incorporating self-cleaning photovoltaic panels for achieving net-zero energy consumption.

### Description of Related Art

The “background” description provided herein is for the purpose of generally presenting the context of the disclosure. Work of the presently named inventors, to the extent it is described in this background section, as well as aspects of the description which may not otherwise qualify as prior art at the time of filing, are neither expressly or impliedly admitted as prior art against the present invention.

Air conditioning systems play a vital role in maintaining comfortable indoor environments, particularly in regions with hot climates. Conventional cooling technologies primarily rely on vapor-compression cycles that use refrigerants and mechanical compressors to achieve the desired cooling effect. These systems typically draw power from the electrical grid and contribute significantly to energy consumption in buildings. Traditional cooling systems face several challenges that limit their effectiveness and sustainability. The use of refrigerants in conventional systems poses environmental concerns due to their high global warming potential. Additionally, the reliance on mechanical compressors increases maintenance requirements and system complexity while generating noise during operation. The dependence on grid power also results in higher operational costs and carbon emissions.

Alternate cooling technologies have been developed to mitigate the environmental harm caused by conventional refrigeration in response to the advent of environmentally conscious engineering [See: AlDayel A, Magdy W (2021) Stance detection on social media: state of the art and trends. Inf Process Manag; Alturayeif N, Luqman H, Ahmed M (2023) A systematic review of machine learning techniques for stance detection and its applications. Neural Comput Appl 35(7):5113-5144]. One of the more recent approaches, thermoelectric air conditioning (TEAC), presents a case for temperature regulation that is environmentally sustainable [See: Chen, X.; Pei, Y.; Ren, Z.; Liu, C.; Yu, X. Recent progress of thermoelectric materials for air-conditioning. Energy 2023, 279, 127832]. TEAC systems offer a cooling solution devoid of refrigerant through the utilization of the Peltier effect, which operates on the principle of temperature fluctuations caused by the electrical current flowing between different materials [See: Riffat, S. B.; Ma, X. Thermoelectrics: A review of present and potential applications. Appl. Therm. Eng. 2003, 23, 913-935; Goldsmid, H. J. Introduction to Thermoelectricity; Springer: Berlin/Heidelberg, Germany, 2010].

Conventional compressor-based air conditioners, despite their extensive utilization, contribute to environmental degradation predominantly due to their reliance on refrigerants that possess a substantial propensity to induce global warming [See: International Energy Agency (IEA). The Future of Cooling; IEA: Paris, France, 2018]. In contrast, thermoelectric modules (TEMs) offer a viable alternative to solid-state components and are widely recognized for their low maintenance requirements, discreet operation, and dependability [See: Shen, L.; Xiao, F.; Chen, Z. A review of thermoelectric cooler for the development of air conditioners. Energy Build. 2021, 237, 110785]. As stated previously, the TE figure of merit (ZT) determines the energy conversion efficiency of these materials through its integration of the Seebeck coefficient, electrical conductivity, and thermal conductivity at a particular temperature [See: Rowe, D. M. CRC Handbook of Thermoelectrics; CRC Press: Boca Raton, FL, USA, 1995; Snyder, G. J.; Toberer, E. S. Complex thermoelectric materials. Nat. Mater. 2008, 7, 105-114].

Notwithstanding the advancements in technology and the advantages they provide, TEACs continue to be underutilized for residential conditioning. Several factors contribute to this constraint, including the comparatively low cooling capacity (typically below 100 W) and the challenges associated with achieving high coefficients of performance (COPs), especially when significant temperature gradients are present [See: Manikandan, S.; Kaushik, S. C.; Saidur, R. A review of thermoelectric air conditioners—Future prospects. Renew. Sustain. Energy Rev. 2016, 60, 1497-1508; Li, D.; Huang, Y.; Fan, X.; Li, J.; Luo, Y. Review of thermoelectric refrigeration with active heat sinks. Appl. Therm. Eng. 2021, 190, 116778]. Under optimal conditions, contemporary commercial thermoelectric modules are capable of attaining peak COPs of as high as eight, owing to the progressive enhancements in efficiency brought about by developments in thermoelectric materials [See: Elsheikh, M. H.; Shnawah, D. A.; Sabri, M. F. M.; Saidur, R.; Hassan, M. Y.; Bashir, M. B. A. A review on thermoelectric renewable energy: Principle parameters that affect their performance. Renew. Sustain. Energy Rev. 1 2014, 30, 337-355; Han, C.; Li, Z.; Dou, S. X. Recent progress in thermoelectric materials. Chin. Sci. Bull. 2014, 59, 2073-2091]. However, they still fail to meet the requirements for extensive implementation.

The efficacy of TEACs can be enhanced by incorporating heat pipes, optimizing airflow, and utilizing water cooling systems, [See: Shen, L.; Xiao, F.; Chen, Z. A review of thermoelectric cooler for the development of air conditioners. Energy Build. 2021, 237, 110785; Li, D.; Huang, Y.; Fan, X.; Li, J.; Luo, Y. Review of thermoelectric refrigeration with active heat sinks. Appl. Therm. Eng. 2021, 190, 116778]. An approach to achieve zero-energy buildings and reduce energy consumption is through the integration of renewable energy sources, such as photovoltaic systems [See: Cuce, E.; Cuce, P. M.; Harputlugil, T.; Hepbasli, A. A comprehensive review on solar assisted heating and cooling systems for buildings. Renew. Sustain. Energy Rev. 2017, 78, 761-795; Hepbasli, A.; Kalinci, Y. A review of heat pump water heating systems. Renew. Sustain. Energy Rev. 2009, 13, 1211-1229].

Significant progress has been achieved in the domain of thermal comfort through the implementation of thermoelectric (TE) cooling technology. However, an emerging sustainable solution in this space is the integration of solar photovoltaic systems with TE air conditioners (SPV-TEAC) [See: Irshad, K.; Habib, K.; Thirumalaiswamy, N.; Saha, B. B. Development of a solar assisted thermoelectric air conditioner (STEAC): An experimental investigation and life cycle assessment. Appl. Energy 2022, 311, 118674]. Khire et al. [See: Khire, R.; Boukhanouf, R.; Ratlamwala, T. A. H. Performance evaluation of an active building wall (ABW) system integrated with thermoelectric cooler and photovoltaic panels for thermal comfort and energy saving. Energy Build. 2018, 174, 404-414] discovered that the effective management of heat flux through the walls and the reduction of cooling burden of the building were both outcomes of active building wall systems incorporating TECs and PV panels. Nevertheless, this research failed to provide a comprehensive analysis of the performance in various climatic conditions or the enduring effects on the sustainability of the structure.

The research conducted by Liu et al. [See: Liu, Y.; Guo, K.; Wang, J.; He, W.; Browne, M. Experimental study of a photovoltaic (PV) powered thermoelectric (TE) radiant wall. Energy Build. 2019, 198, 1-10] regarding a TE radiant wall powered by photovoltaic panels revealed an overall efficiency of 5.5% when passive thermal losses were accounted for. Furthermore, the interior surface temperature of the wall was observed to be 3-8° C. lower than the temperature of the indoor air, indicating encouraging management of heat transfer. The study conducted by Luo et al. [See: Luo, Y.; Li, D.; Huang, Y.; Lan, L.; Li, J. Experimental study on the cooling performance of a solar thermoelectric (TE) ceiling radiant envelope. Energy Build. 2021, 231, examined the impact of increasing photovoltaic electric current on the cooling capacity of a solar TE ceiling envelope. The results of the research emphasized the criticality of optimizing energy input in order to enhance system performance. Experimental testing of STEACS for air conditioning by Irshad et al. [See: Irshad, K.; Habib, K.; Thirumalaiswamy, N.; Saha, B. B. Development of a solar assisted thermoelectric air conditioner (STEAC): An experimental investigation and life cycle assessment. Appl. Energy 2022, 311, 118674] revealed a cooling capacity of over 500 W and an optimal temperature difference, which represented a substantial improvement. Furthermore, their life cycle assessment demonstrated significant yearly energy conservation and a rational repayment period, underscoring the economic feasibility of thermoelectric technology.

According to the findings of Abo-Elmareef et al. [See: Abo-Elmareef, A. M.; Askalany, A. A.; Ali, A. G.; Eltawil, M. A. Performance analysis of a solar-driven thermoelectric air-conditioning system for different PV-input currents under hot climate conditions. Case Stud. Therm. Eng. 2022, 30, 101766], under hot weather conditions, modifying the PV input current could significantly enhance cooling performance of the system, resulting in an optimal design point COP of 2.20. Development and testing of a STERAC system with a hot water supply component by Liu et al. [See: Liu, C.; Chen, X.; Elsheikh, M. H.; He, Y.; Nie, Y. Development of a solar-driven thermoelectric radiant air-conditioning (STERAC) system with hot water supply. Energy Convers. Manag. 2022, 259, 115575] demonstrated that the system could operate effectively as a TE heat pump, with COPs of 2.60 in cooling mode and 3.01 in heating mode, demonstrating its adaptability. Allouhi et al. [See: Allouhi, A.; Benzakour Amine, M.; Kousksou, T.; El Fadar, A. Numerical study of the dynamic behavior of a PV/TE heating system: Influence of the number of thermoelectric modules on the heating COP. Sol. Energy 2022, 243, 563-574] determined the optimal number of TECs for maximal heating COP to be 12 modules by a numerical study of the dynamic behavior of a PV/TE heating system. This highlights the significance of system sizing and configuration in order to optimize performance.

PH12017000164A1 describes a portable solar-powered vaccine carrier including a thermoelectric module between exhaust and cooling fans. A solar panel is located on a sidewall. However, this reference does not mention sliding solar panels on the top having cleaning brushes, sensors connected to a microcontroller for regulating the airflow, or a charging port for a rechargeable battery. In general, this reference does not describe a cooling system.

IN202111049560A describes a self-cleaning and hailstorm protection system for PV modules. The PV modules are attached to rollers that move them into position on a tracker. The self-cleaning is accomplished by cleaning brushes located on the edges of the individual panels so that the panels slide over the cleaning brushes when they move between deployed and non-deployed positions. This reference does not mention thermoelectric modules, intake and exhaust fans, sensors or a microcontroller, or rollers on the bottom of the housing. In general, this reference does not describe a cooling system.

Each of the aforementioned references suffers from one or more drawbacks hindering their adoption, such as limited functionality, lack of integrated self-cleaning mechanisms, and the absence of a comprehensive control system for optimizing energy utilization and cooling performance. Accordingly, it is one object of the present disclosure to provide a solar photovoltaic-powered thermoelectric air conditioning system and a method for using a solar photovoltaic-powered thermoelectric system to cool air which combine the benefits of solar power and thermoelectric cooling while overcoming the limitations of existing solutions. The system and method of the present disclosure integrate multiple features to provide efficient solar energy capture, self-cleaning of the photovoltaic panels, and precise temperature control, resulting in a sustainable and energy-efficient cooling solution.

### SUMMARY

In an exemplary embodiment, a solar photovoltaic-powered thermoelectric system is described, comprising a cabinet including a first wall, a second wall, a third wall, a fourth wall, a top surface and a bottom surface; a plurality of intake air fans located within intake fan openings in the cabinet which extend through the first wall, wherein each intake air fan is surrounded by an intake housing having a heat sink on a back surface and a plurality of air vents on a first side surface and a second side surface, wherein the second side surface is opposite the first side surface; a plurality of outtake cooling fans located within outtake fan openings in the cabinet which extend through the second wall, wherein the second wall is opposite the first wall, wherein each outtake cooling fan is surrounded by an outtake housing having a heat sink on a back surface and a plurality of air vents on a first side surface and a second side surface, wherein the second side surface is opposite the first side surface; a plurality of thermoelectric modules mounted on a panel located at a center of the cabinet between the plurality of back surfaces of the intake cooling fans and the back surfaces of the outtake cooling fans; a sliding mechanism connected to the exterior face of the top surface; a fixed bifacial photovoltaic panel connected to the sliding mechanism; a first sliding bifacial photovoltaic panel and a second sliding bifacial photovoltaic panel connected to the sliding mechanism below the fixed photovoltaic module; an inverter operatively connected to the fixed bifacial photovoltaic panel, the first sliding bifacial photovoltaic panel and the second sliding bifacial photovoltaic panel, wherein the inverter is configured to generate a DC current from power generated by the fixed bifacial photovoltaic panel, the first sliding bifacial photovoltaic panel and the second sliding bifacial photovoltaic panel; at least one rechargeable battery located on the bottom surface, wherein the at least one rechargeable battery is operatively connected to store the DC current from the inverter in a charging cycle; a plurality of sensors located within the cabinet; a microcontroller connected to the at least one rechargeable battery, the inverter, the plurality of intake cooling fans, the plurality of outtake cooling fans, the fixed bifacial photovoltaic panel, the first sliding bifacial photovoltaic panel, the second sliding bifacial photovoltaic panel, the plurality of thermoelectric modules, the plurality of sensors and the sliding mechanism, wherein the microcontroller includes electrical circuitry, a memory storing program instructions and at least one processor configured to execute the program instructions to receive measurement signals from the plurality of sensors, and based on the measurement signals: actuate the sliding mechanism to position the first sliding bifacial photovoltaic panel and the second sliding bifacial photovoltaic panel to receive maximum solar radiation; charge the at least one rechargeable battery with the DC electricity generated by the inverter; provide the DC electrical current from the rechargeable battery to the thermoelectric module; actuate the plurality of intake cooling fans to draw ambient air towards the heat sink on the back surface and expel heated air through the plurality of air vents of the intake housing; and actuate the plurality of outtake cooling fans to draw a cooled air through the plurality of air vents of the outtake housing and expel the cooled air through the plurality of outtake openings in the second side of the cabinet, wherein the plurality of outtake openings are connected to an air duct configured to convey the cooled air into an enclosed area.

In another exemplary embodiment, a method for using a solar photovoltaic-powered thermoelectric system to cool air is described, comprising: turning ON the solar photovoltaic-powered thermoelectric system; providing power from a rechargeable battery located in a lower section of a cabinet surrounding the solar photovoltaic-powered thermoelectric system to a plurality of intake air fans located within intake fan openings in a first wall of the cabinet, wherein the plurality of intake air fans are configured to draw ambient air into an upper section of the cabinet; providing a DC current to a plurality of thermoelectric modules mounted on a panel located at a center of the cabinet, wherein the panel is configured to divide the upper section of the cabinet into a hot side and a cold side; generating, by the DC current, a heated surface on each of the plurality of thermoelectric modules on the hot side and a cooled surface on each of the plurality of thermoelectric modules on the cold side; providing the DC current to a plurality of outtake air fans located within outtake fan openings in a second wall of the cabinet, wherein the plurality of outtake air fans are configured to draw cooled air from the cold side and expel the cooled air through a duct covering the plurality of outtake fan openings; generating, by a plurality of sensors, a plurality of measurement signals; actuating, by a microcontroller including an electrical circuitry, a memory storing program instructions including a load sensing program, and at least one processor configured to execute the program instructions and analyze the plurality of measurement signals based on the load sensing program, a motor of a sliding mechanism connected to the exterior face of a top surface of the cabinet, wherein the sliding mechanism is connected by a linear actuator to a fixed bifacial photovoltaic panel, a first sliding bifacial photovoltaic panel and a second sliding bifacial photovoltaic panel located below the fixed photovoltaic module; generating, during daylight hours, a DC electrical current with the fixed bifacial photovoltaic panel, the first sliding bifacial photovoltaic panel and the second sliding bifacial photovoltaic panel; and recharging the rechargeable battery with the DC electrical current.

The foregoing general description of the illustrative embodiments and the following detailed description thereof are merely exemplary aspects of the teachings of this disclosure and are not restrictive.

### BRIEF DESCRIPTION OF THE DRAWINGS

A more complete appreciation of this disclosure and many of the attendant advantages thereof will be readily obtained as the same becomes better understood by reference to the following detailed description when considered in connection with the accompanying drawings, wherein:

FIG. 1A is an exemplary left perspective diagram of a solar photovoltaic-powered thermoelectric system, according to certain embodiments.

FIG. 1B is an exemplary right perspective diagram of the solar photovoltaic-powered thermoelectric system, according to certain embodiments.

FIG. 1C is an exemplary partial exploded diagram of the solar photovoltaic-powered thermoelectric system, according to certain embodiments.

FIG. 2 is an exemplary partial exploded diagram of a thermoelectric assembly of the solar photovoltaic-powered thermoelectric system, according to certain embodiments.

FIG. 3 is an exemplary sectioned schematic diagram of the thermoelectric assembly depicting its operation in the solar photovoltaic-powered thermoelectric system, according to certain embodiments.

FIG. 4 is an exemplary perspective diagram of a photovoltaic panel assembly of the solar photovoltaic-powered thermoelectric system, according to certain embodiments.

FIG. 5 is an exemplary schematic diagram of operation of the solar photovoltaic-powered thermoelectric system, according to certain embodiments.

FIG. 6 is an exemplary circuit diagram of the solar photovoltaic-powered thermoelectric system, according to certain embodiments.

FIG. 7 is an exemplary perspective diagram of a solar photovoltaic-powered thermoelectric system with sliding bifacial photovoltaic panels in deployed position and incorporating additional photovoltaic panels therein, according to certain embodiments.

FIG. 8 is an exemplary diagram of a solar photovoltaic-powered thermoelectric system incorporating an alternative mechanism for deploying photovoltaic panels therein, according to certain embodiments.

FIG. 9 is an exemplary flowchart of a method for using a solar photovoltaic-powered thermoelectric system to cool air, according to certain embodiments.

FIG. 10 is an exemplary graph representing characteristics of a testing environment for the solar photovoltaic-powered thermoelectric system, according to certain embodiments.

FIG. 11 is an exemplary graph representing temperature measurements recorded at multiple points within the solar photovoltaic-powered thermoelectric system, according to certain embodiments.

FIG. 12 is an exemplary graph representing a relationship between Coefficient of Performance (COP) and cooling capacity (Qc) for the solar photovoltaic-powered thermoelectric system, according to certain embodiments.

FIG. 13 is an illustration of a non-limiting example of details of computing hardware used in a microcontroller of the solar photovoltaic-powered thermoelectric system, according to certain embodiments.

FIG. 14 is an exemplary schematic diagram of a data processing system used within the microcontroller, according to certain embodiments.

FIG. 15 is an exemplary schematic diagram of a processor used with the microcontroller, according to certain embodiments.

FIG. 16 is an illustration of a non-limiting example of distributed components which may share processing with the computing hardware, according to certain embodiments.

### DETAILED DESCRIPTION

In the drawings, like reference numerals designate identical or corresponding parts throughout the several views. Further, as used herein, the words “a”, “an” and the like generally carry a meaning of “one or more”, unless stated otherwise.

Furthermore, the terms “approximately,” “approximate”, “about” and similar terms generally refer to ranges that include the identified value within a margin of 20%, 10%, or preferably 5%, and any values therebetween.

Aspects of this disclosure are directed to a of the solar photovoltaic-powered thermoelectric system and a method for using a solar photovoltaic-powered thermoelectric system to cool air. The system and method of the present disclosure offer a sustainable and energy-efficient alternative to conventional cooling technologies by utilizing solar energy and thermoelectric modules. The system incorporates a unique combination of features, including bifacial photovoltaic panels for efficient solar energy capture, self-cleaning mechanisms to maintain panel efficiency, thermoelectric modules for cooling based on the Peltier effect, energy storage capabilities to support continuous operation, and advanced electronic control systems for automated adjustments. This combination of features addresses the limitations of traditional cooling technologies by providing a sustainable and energy-efficient solution that reduces environmental impact and promotes energy conservation.

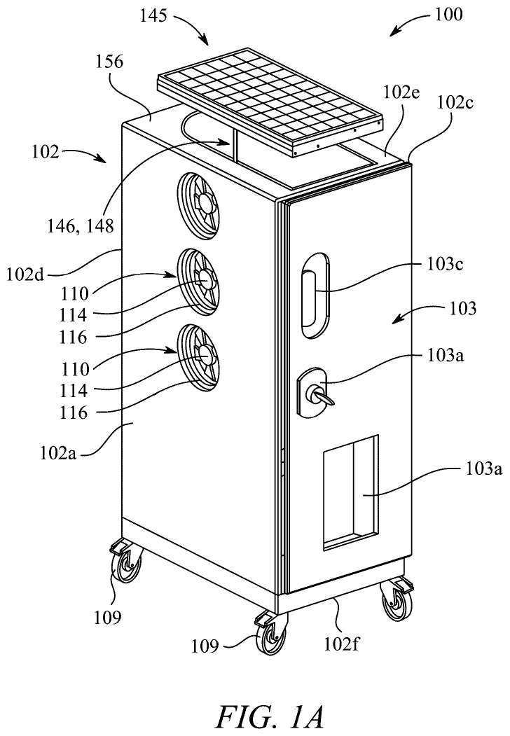

Referring to FIGS. 1A-1C in combination, illustrated are different views of a of the solar photovoltaic-powered thermoelectric system (as represented by reference numeral 100). Specifically, herein, FIG. 1A is an exemplary left perspective diagram of the solar photovoltaic-powered thermoelectric system 100; FIG. 1B is an exemplary right perspective diagram of the solar photovoltaic-powered thermoelectric system 100; and FIG. 1C is an exemplary partial exploded diagram of the solar photovoltaic-powered thermoelectric system 100. The solar photovoltaic-powered thermoelectric system 100 described herein represents an advancement in sustainable cooling technology by combining solar energy harvesting with thermoelectric cooling principles. The solar photovoltaic-powered thermoelectric system 100 integrates photovoltaic power generation, thermal management, and control mechanisms to achieve efficient space cooling without grid power dependency. By utilizing the Peltier effect for cooling and incorporating energy storage capabilities, the solar photovoltaic-powered thermoelectric system 100 can provide consistent cooling performance while maintaining zero net energy consumption. The solar photovoltaic-powered thermoelectric system 100 offers several advantages over traditional cooling technologies, including reduced environmental impact, energy conservation, and enhanced performance. The solar photovoltaic-powered thermoelectric system 100 is also versatile and adaptable, making it suitable for various applications, including remote location cooling, electronic component cooling, and customized cooling needs.

As illustrated, the solar photovoltaic-powered thermoelectric system 100 includes a cabinet 102 including a first wall 102a, a second wall 102b, a third wall 102c, a fourth wall 102d, a top surface 102e and a bottom surface 102f. The cabinet 102 houses the components of the solar photovoltaic-powered thermoelectric system 100. The first wall 102a and the second wall 102b are opposite to each other, and the third wall 102c and the fourth wall 102d are opposite to each other. In particular, the first wall 102a and the second wall 102b are positioned opposite to each other, with the third wall 102c and the fourth wall 102d positioned perpendicular to the first wall 102a and the second wall 102b. The cabinet 102 is sized and dimensioned to accommodate various components of the solar photovoltaic-powered thermoelectric system 100. In an example, the cabinet 102 has a generally square configuration with dimensions of about 1.5 meters by about 1.5 meters. The cabinet 102 is configured to provide structural support and protection for the internal components of the solar photovoltaic-powered thermoelectric system 100.

In an aspect of the present disclosure, the cabinet 102 is made of aluminum. The aluminum construction of the cabinet 102 offers durability and helps to dissipate heat. In alternative examples, the cabinet 102 may be made of iron or stainless steel without limitation. In an example, the cabinet 102 is constructed from a metal sheet with a thickness of 0.72 mm. For purposes of the present disclosure, the cabinet 102 may be constructed from a recycled aluminum material to reduce environmental impact. The cabinet 102 may be further configured to include a high-strength aluminum alloy to improve durability and strength. The cabinet 102 may be further configured to include a lightweight aluminum material to reduce weight and improve portability.

In the solar photovoltaic-powered thermoelectric system 100, the cabinet 102 is configured to provide access to the internal components for maintenance or repair. For purposes of the present disclosure, the cabinet 102 may be configured to include insulation to improve energy efficiency. The cabinet 102 may be further configured to include mounting brackets or supports for internal components. The cabinet 102 may be further configured to include a grounding mechanism for electrical safety. The cabinet 102 may be further configured to include a weatherproof seal to protect the internal components from the elements. The cabinet 102 may be further configured to include a stand or base for stability. The cabinet 102 may be further configured to include a heat-dissipating material to improve cooling efficiency. The cabinet 102 may be further configured to include a sound-dampening material to reduce noise levels. The cabinet 102 may be further configured to include a vibration-dampening material to reduce vibration.

In aspects of the present disclosure, the solar photovoltaic-powered thermoelectric system 100 also includes an access door 103 located on the third wall 102c of the cabinet 102. Herein, as discussed, the third wall 102c is positioned perpendicular to the first wall 102a and the second wall 102b. The access door 103 provides entry to the internal components of the cabinet 102 for maintenance and service operations. The access door 103 may be constructed from aluminum material matching the cabinet 102 to maintain structural integrity and aesthetic uniformity. The access door 103 is configured to provide a weatherproof seal when closed to protect the internal components from environmental elements.

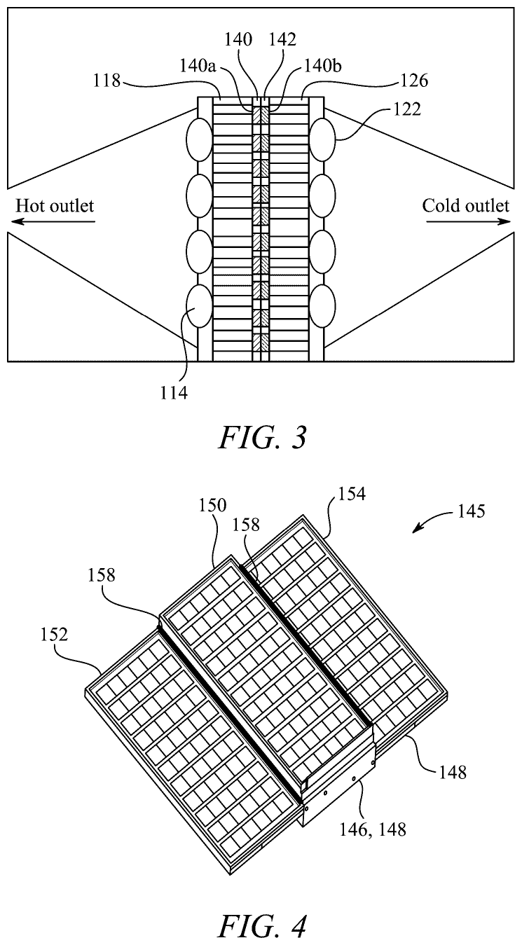

As illustrated, the access door 103 includes an access port cutout 103a, a key lock 103b, and an oval cutout 103c. The access port cutout 103a enables connection of external power cables or diagnostic equipment. The key lock 103b provides security by preventing unauthorized access to the internal components of the solar photovoltaic-powered thermoelectric system 100. The oval cutout 103c is configured to provide access to an ON/OFF button that is operatively connected to a microcontroller 166 (as shown and discussed below in detail with reference to FIG. 5) for controlling operation of the solar photovoltaic-powered thermoelectric system 100. The oval cutout 103c is sized and positioned to allow easy access to the ON/OFF button while maintaining the weatherproof integrity of the cabinet 102.

The cabinet 102 includes an upper compartment 104 adjacent to the top surface 102e and a lower compartment 106 adjacent to the bottom surface 102f. A divider shelf 108 is positioned between the upper compartment 104 and the lower compartment 106. The upper compartment 104 houses the primary cooling components, and the lower compartment 106 houses the electrical components, as discussed below in detail. The divider shelf 108 serves to separate these compartments, providing organization and preventing interference between the different components. The divider shelf 108 may also provide structural support for the cabinet 102. The upper compartment 104 and the lower compartment 106 are sized and configured to accommodate the respective components housed therein. The divider shelf 108 is positioned to optimize the use of space within the cabinet 102. The divider shelf 108 may be removable or adjustable to allow for different configurations of the solar photovoltaic-powered thermoelectric system 100. The divider shelf 108 may be made of a heat-resistant material to prevent heat transfer between the two compartments 104 and 106. The divider shelf 108 may be further configured to include mounting brackets or supports for the components housed within the compartments 104, 106.

In an aspect of the present disclosure, the solar photovoltaic-powered thermoelectric system 100 further includes a plurality of wheels 109 located on an exterior of the bottom surface 102f of the cabinet 102. Each of the plurality of wheels 109 is configured with a locking mechanism (not shown) to secure the cabinet 102 in place during operation. The plurality of wheels 109 enables the solar photovoltaic-powered thermoelectric system 100 to be easily moved across different surfaces while the locking mechanisms prevent unwanted movement when the system is operational. For present purposes, the wheels 109 may be constructed from durable materials suitable for various terrain types, enhancing the portability and versatility of the solar photovoltaic-powered thermoelectric system 100.

The cabinet 102 further includes intake fan openings 110 extending through the first wall 102a and outtake fan openings 112 extending through the second wall 102b. The intake fan openings 110 and the outtake fan openings 112 are positioned in the upper compartment 104 above the divider shelf 108. The intake fan openings 110 allow ambient air to be drawn into the upper compartment 104 (using fans, as discussed later), while the outtake fan openings 112 allow cooled air to be expelled from the upper compartment 104 (again using fans, as discussed later). The positioning of the intake fan openings 110 and the outtake fan openings 112 in the upper compartment 104 above the divider shelf 108 ensures that the airflow is directed through the cooling components, maximizing heat transfer and cooling efficiency. The size and shape of the intake fan openings 110 and the outtake fan openings 112 are designed to optimize airflow and minimize pressure drop. In some examples, the intake fan openings 110 and the outtake fan openings 112 may be further configured to include filters or screens to prevent dust and debris from entering the cabinet 102.

Further, as illustrated, the solar photovoltaic-powered thermoelectric system 100 includes a plurality of intake air fans 114 located within the intake fan openings 110 in the cabinet 102. The intake fan openings 110 extend through the first wall 102a. Each intake air fan 114 operates to draw ambient air into the upper compartment 104 of the cabinet 102. Each intake air fan 114 is surrounded by an intake housing 116. The intake housing 116 includes a heat sink 118 mounted on a back surface 116a of the intake housing 116. The intake housing 116 further includes a first side surface 116b and a second side surface 116c. Herein, the second side surface 116c is positioned opposite to the first side surface 116b. A plurality of air vents 120 extend through both the first side surface 116b and the second side surface 116c of the intake housing 116. In an example configuration, the air vents 120 on the first side surface 116b and the second side surface 116c are configured as rectangular openings measuring approximately 25 millimeters by 100 millimeters. The air vents 120 are arranged in a grid pattern, with five vertical rows of vents on each side surface. The air vents 120 are angled at approximately 30 degrees relative to the horizontal plane to direct airflow efficiently through the intake housing 116. This configuration of the air vents 120 facilitates the movement of air through the intake housing 116 while maintaining optimal pressure and airflow velocity to support the cooling process.

In an example, the heat sink 118 of each intake air fan 114 is constructed from aluminum to facilitate efficient heat transfer. The heat sink 118 includes a series of fins extending perpendicular to the back surface 116a of the intake housing 116. The fins of the heat sink 118 are spaced at intervals of approximately 25 millimeters to optimize air flow and heat dissipation. The heat sink 118 is mounted to the back surface 116a using thermal paste to ensure efficient thermal contact between the heat sink 118 and the back surface 116a. In the solar photovoltaic-powered thermoelectric system 100, the intake air fans 114 are electrically connected to the microcontroller 166 which regulates their operation based on cooling requirements. Each intake air fan 114 is rated to move approximately 220 cubic feet per minute of air at maximum capacity. The intake air fans 114 operate to draw ambient air through the air vents 120 and direct this air across the heat sink 118, where heat transfer occurs through thermal conduction and forced convection.

Further, the solar photovoltaic-powered thermoelectric system 100 includes a plurality of outtake cooling fans 122 located within the outtake fan openings 112 in the cabinet 102. The outtake fan openings 112 extend through the second wall 102b, in which the second wall 102b is positioned opposite to the first wall 102a. Each outtake cooling fan 122 operates to expel cooled air from the upper compartment 104 of the cabinet 102. Each outtake cooling fan 122 is surrounded by an outtake housing 124. The outtake housing 124 includes a heat sink 126 mounted on a back surface 124a of the outtake housing 124. The outtake housing 124 further includes a first side surface 124b and a second side surface 124c. Herein, the second side surface 124c is positioned opposite to the first side surface 124b. A plurality of air vents 128 extend through both the first side surface 124b and the second side surface 124c of the outtake housing 124. In an example configuration, the air vents 128 on the first side surface 124b and the second side surface 124c are configured as rectangular openings measuring approximately 25 millimeters by 100 millimeters. The air vents 128 are arranged in a grid pattern, with five vertical rows of vents on each side surface. The air vents 128 are angled at approximately 30 degrees relative to the horizontal plane to direct airflow efficiently through the outtake housing 124. This configuration of the air vents 128 facilitates the movement of cooled air through the outtake housing 124 while maintaining optimal pressure and airflow velocity to support the cooling process.

In an example, the heat sink 126 of each outtake cooling fan 122 is constructed from aluminum to facilitate efficient heat transfer. The heat sink 126 includes a series of fins extending perpendicular to the back surface 124a of the outtake housing 124. The fins of the heat sink 126 are spaced at intervals of approximately 25 millimeters to optimize air flow and heat dissipation. The heat sink 126 is mounted to the back surface 124a using thermal paste to ensure efficient thermal contact between the heat sink 126 and the back surface 124a. In the solar photovoltaic-powered thermoelectric system 100, the outtake cooling fans 122 are electrically connected to the microcontroller 166 which regulates their operation based on cooling requirements. Each outtake cooling fan 122 is rated to move approximately 360 cubic feet per minute of air at maximum capacity. The outtake cooling fans 122 operate to draw cooled air through the air vents 128 and direct this air across the heat sink 126, where heat transfer occurs through thermal conduction and forced convection.

The solar photovoltaic-powered thermoelectric system 100 further includes an intake fan cover 130 located over each intake fan opening 110. The intake fan cover 130 is configured with louvered vents 132. The louvered vents 132 are angled at approximately 30 degrees relative to the horizontal plane. In an example configuration, each louvered vent 132 has standard opening dimensions of approximately 25 millimeters by 100 millimeters. The louvered vents 132 are designed to effectively direct airflow while maintaining optimal pressure and airflow velocity. The intake fan cover 130 serves to protect the intake air fans 114 and prevent foreign objects from entering the cabinet 102. In present examples, the intake fan cover 130 may be constructed from aluminum material matching the cabinet 102 to maintain structural integrity and aesthetic uniformity.

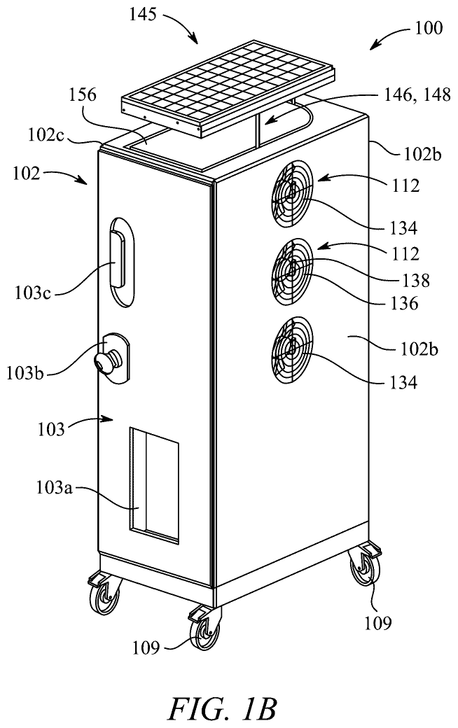

The solar photovoltaic-powered thermoelectric system 100 also includes an outtake fan cover 134 located over each outtake fan opening 112. The outtake fan cover 134 includes an outtake port 136 configured to receive an air duct 138 (as shown in FIG. 2). The outtake fan cover 134 and the outtake port 136 are designed to minimize air leakage and maintain the efficiency of the cooling mechanism in the solar photovoltaic-powered thermoelectric system 100. The outtake port 136 is dimensioned to provide a secure connection with the air duct 138, facilitating efficient transfer of cooled air from the upper compartment 104 to the designated enclosed area. The outtake fan cover 134 serves to protect the outtake cooling fans 122 and prevent foreign objects from entering the cabinet 102. The outtake fan cover 134 may be constructed from aluminum material matching the cabinet 102 to maintain structural integrity and aesthetic uniformity. The air duct 138 is configured to convey the cooled air into an enclosed area requiring temperature control. In an example configuration, the air duct 138 is constructed from flexible material to facilitate installation and routing of the cooled air to the desired location.

The solar photovoltaic-powered thermoelectric system 100 further includes a plurality of thermoelectric modules 140 mounted on a panel 142 located at a center of the cabinet 102 between the back surface 116a of each intake housing 116 and the back surface 124a of each outtake housing 124. The thermoelectric modules 140 operate based on the Peltier effect, in which passing an electric current through the thermoelectric modules 140 creates a temperature differential between opposite sides of each module. Each thermoelectric module 140 is constructed using semiconductor materials, specifically bismuth telluride-based elements arranged in a series of couples. Each couple consists of a positively charged (p-type) and a negatively charged (n-type) semiconductor. These couples are connected electrically in series and thermally in parallel to provide the cooling effect. When direct current is supplied to the thermoelectric modules 140, the hot side adjacent to the intake air fans 114 absorbs heat from the ambient air, while the cold side adjacent to the outtake cooling fans 122 releases cooled air for circulation into the enclosed area.

The panel 142 serves as a mounting surface for the thermoelectric modules 140, providing structural support and ensuring proper alignment. The panel 142 may be made of a thermally conductive material to enhance heat transfer. In an example, the panel 142 is constructed of polymethyl methacrylate material (plexiglass, or specifically Perspex® by Perspex Acrylic, Lancashire) providing a stable mounting surface for the thermoelectric modules 140 while maintaining thermal isolation between the hot and cold sides of the solar photovoltaic-powered thermoelectric system 100. The panel 142 may also include features such as heat spreaders or thermal interface materials to further improve thermal performance. In an example configuration, as may be understood from FIG. 1C, the panel 142 extends vertically across the upper compartment 104 of the cabinet 102, effectively dividing it into a hot zone adjacent to the first wall 102a and a cold zone adjacent to the second wall 102b. The thermoelectric modules 140 are mounted on the panel 142 in a configuration that aligns with the positions of the intake air fans 114 and the outtake cooling fans 122. In an example configuration, the intake air fans 114 and the outtake cooling fans 122 are axial fans used to regulate airflow. The thermoelectric modules 140 may be electrically connected in series or parallel to achieve the desired cooling capacity. In some examples, the thermoelectric modules 140 may be further configured to include temperature sensors or other monitoring devices to provide feedback to the microcontroller 166, for efficient operations of the solar photovoltaic-powered thermoelectric system 100.

Referring to FIG. 2, illustrated is an exemplary partial exploded diagram of a thermoelectric assembly 200 of the solar photovoltaic-powered thermoelectric system 100. The thermoelectric assembly 200 represents arrangement of various components, including the intake housing 116 with the intake air fan 114 and the heat sink 118, the outtake housing 124 with the outtake cooling fan 122 and the heat sink 126, and the thermoelectric module 140, to create an efficient thermal management system. Herein, the thermoelectric module 140 creates a temperature differential, with the intake air fan 114 and the outtake cooling fan 122 facilitating air movement across their respective heat sinks to enhance the cooling effect. The intake housing 116 and the outtake housing 124 are positioned on opposite sides of the thermoelectric module 140. The heat sink 118 of each intake air fan 114 is mounted with a thermal paste (not shown) to a hot side 140a of one of the plurality of thermoelectric modules 140. Similarly, the heat sink 126 of each outtake cooling fan 122 is mounted with the thermal paste to a cold side 140b of one of the plurality of thermoelectric modules 140.

The thermal paste, as used herein, is a thermally conductive compound that fills microscopic air gaps between the mating surfaces to maximize thermal conductivity. In present configuration, the thermal paste is applied in a thin, uniform layer to ensure efficient thermal contact between the respective heat sinks and the thermoelectric modules 140. The thermal paste has a thermal conductivity rating of approximately 8.5 watts per meter Kelvin to facilitate efficient heat transfer. In an example, the thermal paste may be selected from materials such as metal oxide compounds or silver-based compounds to provide enhanced thermal conductivity while maintaining electrical isolation between the components. The mounting arrangement using the thermal paste enables effective thermal coupling between the heat sinks and their respective sides of the thermoelectric modules 140, enhancing the overall heat transfer efficiency of the solar photovoltaic-powered thermoelectric system 100.

As discussed, the heat sink 118 of the intake housing 116 is in thermal contact with the hot side 140a of the thermoelectric module 140, while the heat sink 126 of the outtake housing 124 is in thermal contact with the cold side 140b of the thermoelectric module 140. During operation, the intake air fan 114 draws ambient air into the intake housing 116, where it passes over the heat sink 118 and absorbs heat from the hot side 140a of the thermoelectric module 140. The outtake cooling fan 122 draws cooled air from the cold side 140b of the thermoelectric module 140 and expels it from the outtake housing 124. The intake fan openings 110 and outtake fan openings 112 are positioned on opposite walls of the cabinet 102 to enable cross-ventilation. The intake fan openings 110 in the first wall 102a and the outtake fan openings 112 in the second wall 102b ensure continuous airflow through the solar photovoltaic-powered thermoelectric system 100, facilitating the heat exchange process of the thermoelectric modules 140. This configuration facilitates efficient heat transfer and cooling within the thermoelectric assembly 200, thereby providing the cooling effect in the solar photovoltaic-powered thermoelectric system 100.

In the solar photovoltaic-powered thermoelectric system 100, the plurality of intake air fans 114, the plurality of outtake cooling fans 122, the intake fan openings 110 in the first wall 102a, the outtake fan openings 112 in the second wall 102b, and the panel 142 are all located in the upper compartment 104. This arrangement in the upper compartment 104 creates a dedicated cooling zone separated from the electrical components housed in the lower compartment 106. The intake fan openings 110 and the outtake fan openings 112 are positioned at corresponding heights within the upper compartment 104 to facilitate efficient cross-flow ventilation. The panel 142 is mounted in the upper compartment 104 at a position that optimizes the air flow path between the intake air fans 114 and the outtake cooling fans 122. This configuration provides that the ambient air drawn in through the intake fan openings 110 flows efficiently across the thermoelectric modules 140 mounted on the panel 142 before being expelled as cooled air through the outtake fan openings 112. The positioning of these components within the upper compartment 104 helps to isolate the heat generated by the thermoelectric modules 140 from the electrical components located in the lower compartment 106.

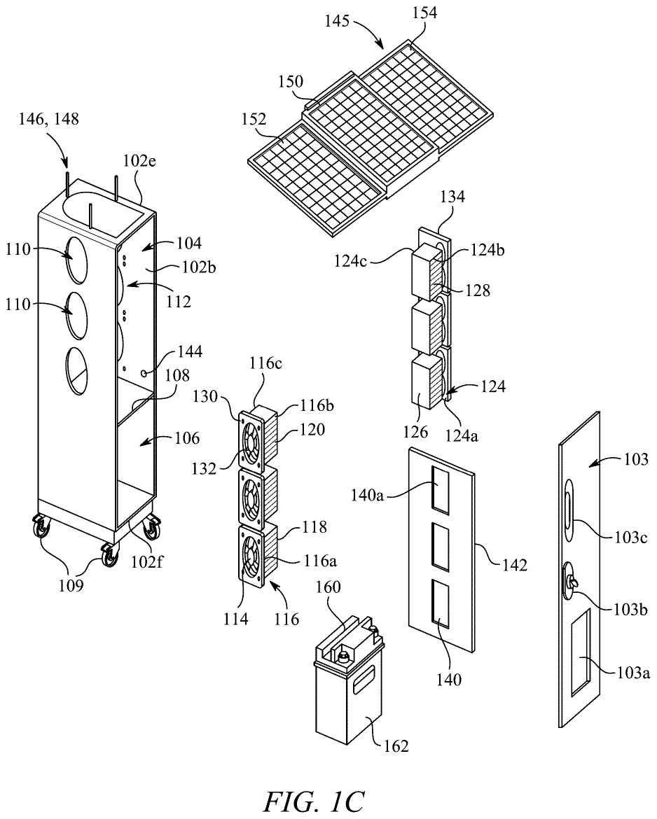

Referring to FIG. 3, illustrated is an exemplary sectioned diagram of the thermoelectric assembly depicting its cooling operation in the solar photovoltaic-powered thermoelectric system 100. The thermoelectric assembly includes narrow channels on both sides of the panel 142. In an example, the channels may have a width of approximately 11.12 inches, the panel 142 may have a width of approximately 11.12 inches and extends vertically within the cabinet 102 having a height of approximately 35.2 inches. These narrow channels are designed based on the Bernoulli principle, wherein the decreased cross-sectional area increases air velocity, thereby enhancing convective heat transfer. The thermoelectric modules 140 are mounted on the panel 142, with their hot sides 140a and cold sides 140b positioned on opposite faces. Heat sinks 118, 126, constructed from high thermal conductivity materials such as aluminum or copper, are mounted in thermal contact with the respective hot and cold sides of the thermoelectric modules 140 to facilitate efficient heat conduction. The intake air fans 114 and the outtake cooling fans 122, arranged in vertical arrays along both sides of the panel 142, enhance convective heat transfer by moving air rapidly across the heat sink surfaces. As air passes through these narrow channels, its prolonged exposure to the cold ceramic surface of the thermoelectric modules 140 facilitates additional cooling, with moisture content condensing during the process. Heated air exits through the hot outlet on the left side while cooled, dehumidified air exits through the cold outlet on the right side. The temperature reduction achieved through this configuration is larger compared to a wider channel design due to the combination of increased air velocity and enhanced heat transfer in the narrow channel.

Referring back to FIGS. 1A-1C in combination, as illustrated, the solar photovoltaic-powered thermoelectric system 100 further includes a drain port 144 located in the upper compartment 104 on the second wall 102b adjacent to the divider shelf 108. The drain port 144 is positioned to collect condensed water that forms during the cooling process as warm, humid air contacts the cold surfaces of the heat sink 126 and the cold side 140b of the thermoelectric modules 140. The drain port 144 is connected to a drain line (not shown) that extends from the drain port 144 to the exterior of the cabinet 102. The drain line is configured to convey the condensed water from the cabinet 102 using gravitational flow. The positioning of the drain port 144 adjacent to the divider shelf 108 enables effective collection of condensate from the cooling process while preventing any water accumulation that could affect the electrical components in the lower compartment 106.

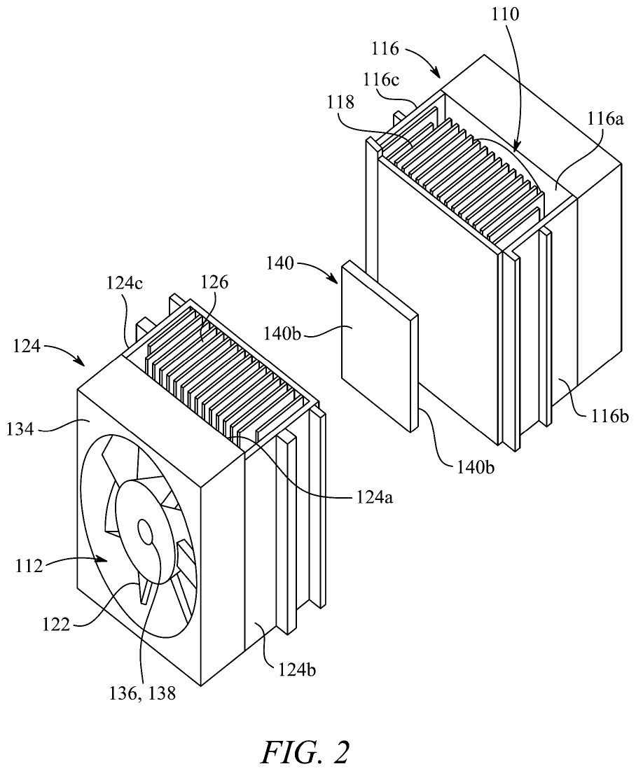

Referring again to FIGS. 1A-1C in combination, as illustrated, the solar photovoltaic-powered thermoelectric system 100 includes a photovoltaic panel assembly 145. FIG. 4 is an exemplary perspective diagram of the photovoltaic panel assembly 145 of the solar photovoltaic-powered thermoelectric system 100. As illustrated in FIGS. 1A-1C and FIG. 4 in conjunction, the solar photovoltaic-powered thermoelectric system 100 includes a sliding mechanism 146 connected to an exterior face of the top surface 102e of the cabinet 102. The sliding mechanism 146 includes a linear actuator 148 configured to enable horizontal movement of photovoltaic panels (as discussed hereinafter). The solar photovoltaic-powered thermoelectric system 100 also includes a fixed bifacial photovoltaic panel 150 connected to the sliding mechanism 146. Further, the solar photovoltaic-powered thermoelectric system 100 includes a first sliding bifacial photovoltaic panel 152 and a second sliding bifacial photovoltaic panel 154 connected to the sliding mechanism 146 below the fixed bifacial photovoltaic panel 150. The sliding mechanism 146 facilitates the first sliding bifacial photovoltaic panel 152 and the second sliding bifacial photovoltaic panel 154 to move horizontally in a manner similar to a matchbox opening and closing. The fixed bifacial photovoltaic panel 150, the first sliding bifacial photovoltaic panel 152, and the second sliding bifacial photovoltaic panel 154 are configured to capture solar energy and convert it into electrical energy to power the solar photovoltaic-powered thermoelectric system 100. The bifacial photovoltaic panels 150-154 are capable of capturing solar energy from both sides, increasing the efficiency of solar energy capture. Herein, the fixed bifacial photovoltaic panel 150 remains stationary while the sliding mechanism 146 enables the first sliding bifacial photovoltaic panel 152 and the second sliding bifacial photovoltaic panel 154 to move independently to optimize solar energy capture. This configuration allows the panels 150-154 to create varying degrees of overlap or separation to maximize exposure to available sunlight. Table 1 (below) provides exemplary specifications for the panels 150-154 as utilized for purposes of the present disclosure.

TABLE 1
PV panel specification

| Dimensions | 64.57 × 26.57 × 1.18 in | |
|---|---|---|
| Weight | 26.5 | Lbs |
| W | 210 | |
| Rated Voltage [Vmpp] | 20 | V |
| Rated Current [Impp] | 10.5 | A |
| Open Circuit Voltage [Voc] | 24.5 | V |
| Short Circuit Current [Isc] | 12.5 | A |
| Max Series Fuse Rating | 20 | A |
| Power Temp Coefficient | −0.45%/° C. | |
| Voltage Temp Coefficient | −0.37%/° C. | |
| Current Temp Coefficient | 0.1%/° C. | |
| Max. System Voltage | 1000 | VDC |

The sliding mechanism 146 allows the photovoltaic panels 150-154 to be positioned to receive maximum solar radiation throughout the day. The sliding mechanism 146 may be configured to include a tracking system that automatically adjusts the position of the photovoltaic panels 150-154 based on position of the sun. The sliding mechanism 146 may also be configured to retract the photovoltaic panels 150-154 for protection during inclement weather or when not in use. In an example, the fixed bifacial photovoltaic panel 150, the first sliding bifacial photovoltaic panel 152, and the second sliding bifacial photovoltaic panel 154 are each rated at about 400 watts and constructed using monocrystalline silicon with bifacial technology to capture sunlight from both front and rear surfaces. Further, the linear actuator 148 of the sliding mechanism 146 has a retracted length of approximately 435 millimeters and an extended length of approximately 700 millimeters, providing a stroke length of approximately 170 millimeters. The linear actuator 148 operates on 24 volts DC power and includes an integrated Hall effect sensor for accurate position feedback. The linear actuator 148 moves at a speed of approximately 10 millimeters per second at maximum load capacity of 1000 newtons. Table 2 (below) provides exemplary specifications for the linear actuator 148 as utilized for purposes of the present disclosure.

TABLE 2
Linear Actuator Specification

| Type | Electric Linear Actuator | |
|---|---|---|
| Retracted Length | 435 | mm |
| Extended Length | 700 | mm |
| Stroke Length | 170 | mm |
| Load capacity | 1000N | |
| Speed | 10 mm/s (at maximum load) | |
| Operating Voltage | 24 | V DC |

| | |
|---|---|
| Motor Type | DC |
| Hall Sensor | Integrated Hall Effect Sensor |
| | for accurate position feedback |

The solar photovoltaic-powered thermoelectric system 100 further includes a reflective layer 156 configured to cover an exterior face of the top surface 102e of the cabinet 102. The reflective layer 156 is positioned beneath the sliding mechanism 146 to redirect sunlight onto the rear surfaces of the fixed bifacial photovoltaic panel 150, the first sliding bifacial photovoltaic panel 152, and the second sliding bifacial photovoltaic panel 154. The reflective layer 156 is constructed from a highly reflective material to maximize the redirection of incident sunlight. In an example configuration, the reflective layer 156 extends across the entire exterior face of the top surface 102e to provide uniform reflection of sunlight. The reflective layer 156 enhances the overall energy capture efficiency of the bifacial photovoltaic panels 150-154 by enabling them to capture reflected sunlight on their rear surfaces in addition to direct sunlight on their front surfaces. The reflective layer 156 is securely fastened to the top surface 102e to maintain consistent positioning relative to the photovoltaic panels. The positioning of the reflective layer 156 beneath the sliding mechanism 146 ensures that it remains protected from environmental elements while maintaining its reflective properties.

In an aspect of the present disclosure, the solar photovoltaic-powered thermoelectric system 100 further includes a plurality of self-cleaning brushes 158 located on the sliding mechanism 146. The plurality of self-cleaning brushes 158 are configured to brush a surface of the first sliding bifacial photovoltaic panel 152 and a surface of the second sliding bifacial photovoltaic panel 154 as these panels slide past the plurality of self-cleaning brushes 158. As better shown in FIG. 4, each of the plurality of self-cleaning brushes 158 is mounted at a corner of the fixed bifacial photovoltaic panel 150. Specifically, as the first sliding bifacial photovoltaic panel 152 and the second sliding bifacial photovoltaic panel 154 move horizontally beneath the fixed bifacial photovoltaic panel 150 during nighttime operation, the plurality of self-cleaning brushes 158 engage with the panel surfaces to sweep away accumulated dust and debris. This cleaning action occurs before the panels overlap, ensuring the surfaces remain clean for optimal performance during subsequent daytime operation. The plurality of self-cleaning brushes 158 are constructed using materials effective at removing dust and debris without causing damage to the surfaces of the photovoltaic panels 152, 154. The cleaning action of the plurality of self-cleaning brushes 158 maintains the efficiency of the photovoltaic panels 152, 154 by preventing the buildup of materials that could reduce solar energy absorption.

In an exemplary configuration of the solar photovoltaic-powered thermoelectric system 100, the microcontroller 166 regulates the operation timing of the plurality of self-cleaning brushes 158 through programmed intervals. The cleaning cycles are initiated based on environmental condition data from the plurality of sensors 164, including real-time feedback of panel surface conditions. The microcontroller 166 activates the sliding mechanism 146 to engage the plurality of self-cleaning brushes 158 with the surfaces of the first sliding bifacial photovoltaic panel 152 and the second sliding bifacial photovoltaic panel 154, based on the determined timings for highly efficient power generation thereby.

Further, as illustrated in FIGS. 1A-1C in combination, the solar photovoltaic-powered thermoelectric system 100 includes an inverter 160 operatively connected to the fixed bifacial photovoltaic panel 150, the first sliding bifacial photovoltaic panel 152, and the second sliding bifacial photovoltaic panel 154. The inverter 160 is configured to generate a DC current from power generated by the fixed bifacial photovoltaic panel 150, the first sliding bifacial photovoltaic panel 152, and the second sliding bifacial photovoltaic panel 154. The inverter 160 converts the variable DC power generated by the photovoltaic panels 150-154 into a stable DC current suitable for charging a rechargeable battery and powering the thermoelectric modules 140. The inverter 160 includes protective features such as overcharge protection, short circuit protection, and thermal protection to ensure safe and reliable operation of the solar photovoltaic-powered thermoelectric system 100.

In an example configuration, the inverter 160 has a peak power rating of 7000 watts and produces a pure sine wave output. The inverter 160 is configured to receive a maximum input power of 4800 watts from the combined output of the photovoltaic panels. The inverter 160 includes maximum power point tracking (MPPT) functionality to optimize power generation from the photovoltaic panels 150-154. The inverter 160 may also include safety features such as overcurrent protection, overvoltage protection, reverse polarity protection, and the like. Each photovoltaic panel 150-154 is configured with a rated voltage of 20 volts and a rated current of 10.5 amperes at maximum power point. The photovoltaic panels 150-154 have an open circuit voltage of 24.5 volts and a short circuit current of 12.5 amperes. The inverter 160 is configured to handle these input parameters while maintaining an output frequency of 50 hertz±0.3% or 60 hertz±0.3%.

The solar photovoltaic-powered thermoelectric system 100 further includes at least one rechargeable battery 162 located on the bottom surface 102f of the cabinet 102. The at least one rechargeable battery 162 is operatively connected to store the DC current from the inverter 160 in a charging cycle. The at least one rechargeable battery 162 is configured to store excess energy generated by the fixed bifacial photovoltaic panel 150, the first sliding bifacial photovoltaic panel 152, and the second sliding bifacial photovoltaic panel 154 during periods of high solar radiation. This stored energy is then available to power the thermoelectric modules 140 and associated components during periods of low solar radiation or increased cooling demand. In an example configuration, the at least one rechargeable battery 162 comprises four 200 ampere-hour 12-volt GEL deep cycle batteries connected in a battery array. The GEL deep cycle batteries are specifically selected for ability to withstand deep discharge cycles, making them suitable for solar power applications. Each battery in the array provides a capacity of 200 ampere-hours at 12 volts, with an internal resistance of approximately 3.5 milliohms.

In the present configuration, the at least one rechargeable battery 162 is positioned in the lower compartment 106. This provides that the at least one rechargeable battery 162 is separated from the heated components in the upper compartment 104. The placement of the at least one rechargeable battery 162 in the lower compartment 106 also provides stability to structure of the solar photovoltaic-powered thermoelectric system 100 due to the weight of the batteries, while maintaining thermal isolation from the heated components in the upper compartment 104. For this configuration, the lower compartment 106 may be configured with appropriate ventilation to manage any heat generated by the at least one rechargeable battery 162 during charging and discharging cycles.

Referring now to FIG. 5, illustrated is an exemplary schematic diagram of the operation of the solar photovoltaic-powered thermoelectric system 100. As shown, the solar photovoltaic-powered thermoelectric system 100 includes a plurality of sensors 164. The plurality of sensors 164 are located within the cabinet 102. In an aspect, the plurality of sensors 164 include at least one temperature sensor, at least one relative humidity sensor, and at least one solar radiation intensity sensor. The at least one temperature sensor is configured to measure ambient temperature and temperature differentials across the thermoelectric modules 140. The at least one relative humidity sensor is configured to monitor moisture content in the air before and after cooling. The at least one solar radiation intensity sensor is configured to measure the intensity and angle of incident sunlight throughout operation. The plurality of sensors 164 are strategically positioned within the cabinet 102 to provide comprehensive monitoring of environmental conditions affecting the performance of the solar photovoltaic-powered thermoelectric system 100.

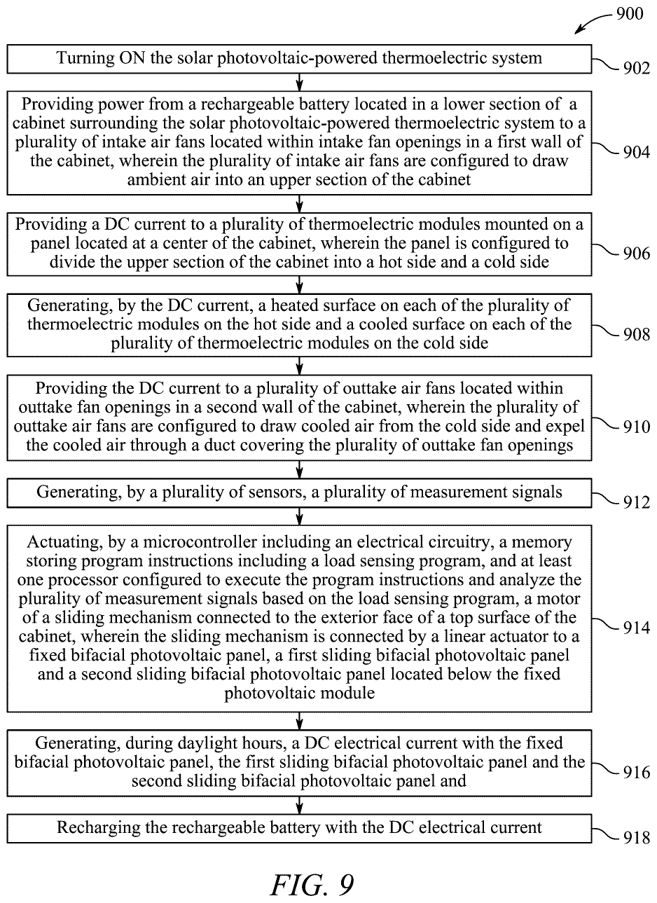

The solar photovoltaic-powered thermoelectric system 100 further includes the microcontroller 166 that is operatively connected to and controls multiple components thereof. Although not depicted in drawings, the microcontroller 166 is connected to the at least one rechargeable battery 162 to manage charging and power distribution, to the inverter 160 to regulate power conversion, to the plurality of intake air fans 114 and the plurality of outtake cooling fans 122 to control airflow, to the fixed bifacial photovoltaic panel 150, the first sliding bifacial photovoltaic panel 152, and the second sliding bifacial photovoltaic panel 154 to monitor power generation, to the plurality of thermoelectric modules 140 to regulate cooling operation, to the plurality of sensors 164 to receive environmental data and to the sliding mechanism 146 to control panel positioning. The microcontroller 166 includes electrical circuitry for signal processing and component interface, a memory storing program instructions including a load sensing program, and at least one processor configured to execute these program instructions. The processor of the microcontroller 166 is configured to receive and process the measurement signals from the plurality of sensors 164. Further details about the microcontroller 166 are discussed below in the description in reference to FIGS. 9-13.

Herein, the measurement signals include temperature signals from the temperature sensors, relative humidity signals from the relative humidity sensors, and solar radiation intensity signals from the solar radiation intensity sensors. The temperature signals indicate the temperature readings at various points within the solar photovoltaic-powered thermoelectric system 100, enabling the microcontroller 166 to monitor and optimize the cooling process. The relative humidity signals provide data about moisture levels in the air, allowing the microcontroller 166 to adjust operation for optimal dehumidification. The solar radiation intensity signals enable the microcontroller 166 to determine the optimal positioning of the photovoltaic panels for maximum solar energy capture. The plurality of sensors 164 provide continuous real-time data to the microcontroller 166, enabling dynamic adjustment of operations of the solar photovoltaic-powered thermoelectric system 100 based on changing environmental conditions. Based on analysis of these measurement signals, the microcontroller 166 executes control algorithms stored in the memory to optimize the operation of the solar photovoltaic-powered thermoelectric system 100 by adjusting component parameters in real-time to maintain efficient cooling while maximizing energy utilization.

Specifically, herein, the microcontroller 166 is configured to actuate the sliding mechanism 146 to position the first sliding bifacial photovoltaic panel 152 and the second sliding bifacial photovoltaic panel 154 to receive maximum solar radiation. Based on solar radiation intensity signals from the sensors 164, the microcontroller 166 executes the load sensing program to determine optimal panel positions. The microcontroller 166 then generates drive signals which actuate the linear actuator 148 attached to the sliding mechanism 146, causing horizontal movement of the panels. The linear actuator 148 operates with a feedback system 168 providing continuous position data via the integrated Hall effect sensor to ensure precise positioning for maximum solar energy capture.

Herein, the load sensing program in the microcontroller 166 continuously monitors cooling requirements through the plurality of sensors 164 and adjusts power distribution accordingly. The microcontroller 166 regulates supplied power to match cooling demands, optimizing energy consumption and extending operational life of the at least one rechargeable battery 162. The microcontroller 166 implements protective measures including overcharge protection, deep discharge prevention, and thermal overload protection for the at least one rechargeable battery 162.

In some examples, the microcontroller 166 may be programmed to automatically adjust the sliding mechanism 146 based on cooling requirements. During periods of high cooling demand, the microcontroller 166 positions the first sliding bifacial photovoltaic panel 152 and the second sliding bifacial photovoltaic panel 154 to maximize solar energy capture. The solar radiation intensity sensor of the plurality of sensors 164 provides data about sunlight intensity and angle to the microcontroller 166. The microcontroller 166 processes this data to determine the optimal positioning and timing of panel adjustments through the linear actuator 148, thereby optimizing solar energy collection throughout operational periods.

The microcontroller 166 is further configured to charge the at least one rechargeable battery 162 with the DC electricity generated by the inverter 160. The microcontroller 166 monitors power generation from the fixed bifacial photovoltaic panel 150, the first sliding bifacial photovoltaic panel 152, and the second sliding bifacial photovoltaic panel 154, which together can provide up to 4800 watts of input power. Based on this monitoring, the microcontroller 166 controls the inverter 160 to convert the variable DC power into stable DC current suitable for charging the 200 ampere-hour batteries while maintaining protective features such as overcharge protection and thermal protection.

The microcontroller 166 is further configured to provide the DC electrical current from the rechargeable battery 162 to the plurality of thermoelectric modules 140. Based on temperature signals from the sensors 164, the microcontroller 166 regulates the current supply to maintain optimal temperature differentials across the thermoelectric modules 140. This controlled current flow enables efficient operation of the Peltier effect, where one side of each thermoelectric module 140 becomes cold by absorbing heat while the opposite side of each thermoelectric module 140 releases heat.

The microcontroller 166 is further configured to actuate the plurality of intake air fans 114 to draw ambient air towards the heat sink 118 on the back surface 116a and expel heated air through the plurality of air vents 120 of the intake housing 116. Based on temperature signals and cooling requirements, the microcontroller 166 controls the intake air fans 114 to operate at speeds up to 220 cubic feet per minute. This operation draws ambient air across the heat sink 118, where heat is absorbed from the hot sides 140a of the thermoelectric modules 140, before being expelled through the air vents 120 on the first side surface 116b and the second side surface 116c of the intake housing 116.

The microcontroller 166 is further configured to actuate the plurality of outtake cooling fans 122 to draw cooled air through the plurality of air vents 128 of the outtake housing 124 and expel the cooled air through the plurality of outtake openings 112 in the second wall 102b of the cabinet 102. Based on temperature signals and relative humidity signals from the sensors 164, the microcontroller 166 controls the operation speed of the outtake cooling fans 122 up to 360 cubic feet per minute. The cooled air is drawn through the air vents 128. As the air passes over the heat sink 126 mounted with thermal paste to the cold side 140b of the thermoelectric modules 140, the air temperature drops and moisture content condenses, resulting in cooled and dehumidified air being expelled through the outtake openings 112.

Herein, the outtake openings 112 in the second wall 102b of the cabinet 102 are connected to the air duct 138 which is configured to convey the cooled air into an enclosed area. The air duct 138 is constructed from flexible material to facilitate installation and routing of the cooled air to desired locations. The connection between the outtake openings 112 and the air duct 138 is established through the outtake port 136 of the outtake fan cover 134. This configuration enables the cooled and dehumidified air to be efficiently directed to specific areas requiring temperature control while minimizing thermal losses during transfer.

In general, the microcontroller 166 executes program instructions stored in memory to control the operation of the sliding mechanism 146 in the solar photovoltaic-powered thermoelectric system 100. The microcontroller 166 receives measurement signals from the plurality of sensors 164 including solar radiation intensity signals and processes these signals to determine optimal positioning of the photovoltaic panels 150-154. Based on this analysis, the microcontroller 166 generates drive signals to actuate the linear actuator 148 attached to the sliding mechanism 146. The linear actuator 148 extends or retracts in response to these drive signals, causing horizontal movement of the first sliding bifacial photovoltaic panel 152 and the second sliding bifacial photovoltaic panel 154. The feedback system 168 continuously monitors the position and movement of the sliding mechanism 146 through the integrated Hall effect sensor in the linear actuator 148, providing real-time position data back to the microcontroller 166.

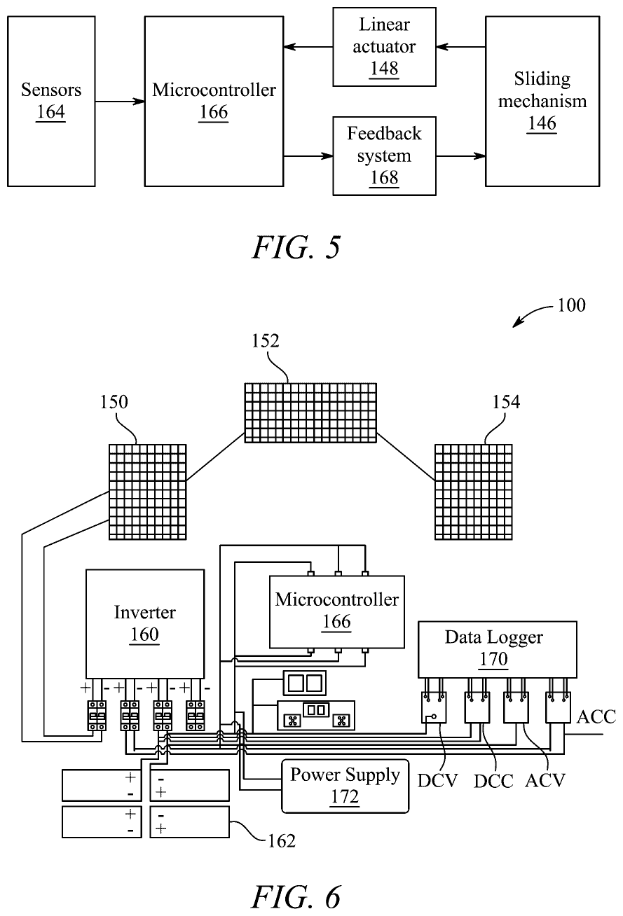

Referring to FIG. 6, illustrated is an exemplary schematic diagram showing electrical connections between components of the solar photovoltaic-powered thermoelectric system 100. FIG. 6 illustrates how the solar energy captured by the photovoltaic panels 150-154 is converted by the inverter 160, stored in the at least one rechargeable battery 162, and managed by the microcontroller 166 to power the thermoelectric cooling components of the solar photovoltaic-powered thermoelectric system 100. As shown, the fixed bifacial photovoltaic panel 150, the first sliding bifacial photovoltaic panel 152, and the second sliding bifacial photovoltaic panel 154 are electrically connected to the inverter 160. The inverter 160 is connected to the at least one rechargeable battery 162, which comprises multiple battery units connected in an array configuration. The microcontroller 166 is connected to both the inverter 160 and the at least one rechargeable battery 162 to manage power conversion and storage. The microcontroller 166 includes push buttons for manual interface and control of the system operations. A data logger 170 is connected to the microcontroller 166 to record operational data including temperature signals, relative humidity signals, and solar radiation intensity signals from the plurality of sensors 164. A power supply 172 provides regulated power to the microcontroller 166 and associated control components. The entire electrical system is configured with appropriate wiring and connections to enable efficient power distribution and system control while maintaining electrical safety standards.

In an aspect of the present disclosure, the solar photovoltaic-powered thermoelectric system 100 further includes a motor (not shown) that incorporates the linear actuator 148 attached to the sliding mechanism 146. Further, the load sensing program is stored in the memory of the microcontroller 166 to optimize the positioning of the photovoltaic panels 150-154. The load sensing program includes algorithms for processing environmental data and calculating optimal panel positions to maximize solar energy capture while protecting system components. The at least one processor of the microcontroller 166 is configured to execute the load sensing program based on multiple sensor inputs. The processor receives temperature signals from the temperature sensor indicating ambient temperature and temperature differentials across the thermoelectric modules 140, relative humidity signals from the relative humidity sensor measuring moisture content in the air, and solar radiation intensity signals from the solar radiation intensity sensor measuring the intensity and angle of incident sunlight. Based on analysis of these measurement signals, the processor executes the load sensing program to generate appropriate drive signals. These drive signals actuate the motor to extend or retract the linear actuator 148 through its 170-millimeter stroke length, thereby moving the sliding mechanism 146 to position the photovoltaic panels for maximum solar radiation capture. The integrated Hall effect sensor in the linear actuator 148 provides continuous position feedback to the microcontroller 166, enabling precise control of panel positioning based on the environmental conditions detected by the plurality of sensors 164. In an example configuration, the motor has a load capacity of 1000 newtons and operates at approximately 10 millimeters per second, enabling controlled movement of the first sliding bifacial photovoltaic panel 152 and the second sliding bifacial photovoltaic panel 154.

In an aspect, the solar photovoltaic-powered thermoelectric system 100 further includes a remote control mechanism (not shown) configured to turn ON the microcontroller 166 and generate drive signals which actuate the motor including a linear actuator attached to the sliding mechanism 146. Herein, the remote control mechanism sends wireless activation signals to the microcontroller 166 through a receiver interface, providing an alternative to manual activation through the ON/OFF button accessible via the oval cutout 103c in the access door 103. When the activation signal is received, the microcontroller 166 initiates a startup sequence that includes: verifying the charge state of the at least one rechargeable battery 162, checking the status of all connected components through the electrical circuitry, and beginning the execution of stored program instructions. The remote control mechanism enables convenient system activation from a distance, particularly useful when the solar photovoltaic-powered thermoelectric system 100 is installed in locations where direct access to the cabinet 102 is limited or impractical. The microcontroller 166 confirms successful system activation by initiating operation of the cooling components and panel positioning system according to the current environmental conditions detected by the plurality of sensors 164.

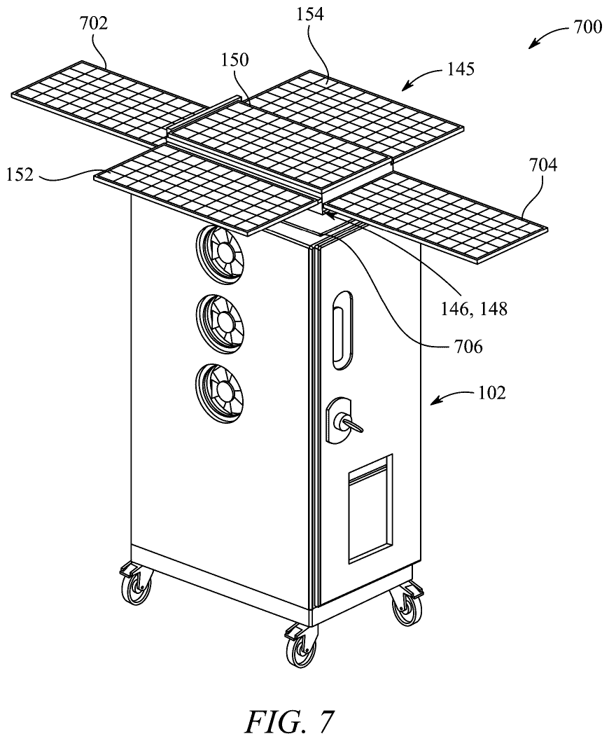

Referring to FIG. 7, illustrated is an exemplary perspective view of a solar photovoltaic-powered thermoelectric system 700 showing an alternate configuration with additional photovoltaic panels in a deployed state. In this configuration, the fixed bifacial photovoltaic panel 150, the first sliding bifacial photovoltaic panel 152, and the second sliding bifacial photovoltaic panel 154 are deployed horizontally above the cabinet 102 using the sliding mechanism 146 and the linear actuator 148 as previously described. Additionally, this configuration includes a first side bifacial photovoltaic panel 702 and a second side bifacial photovoltaic panel 704 connected to the cabinet 102 by a second sliding mechanism 706. The second sliding mechanism 706 may include additional linear actuators (not shown) configured to deploy the first side bifacial photovoltaic panel 702 and the second side bifacial photovoltaic panel 704 perpendicular to the orientation of panels 150, 152, and 154. This perpendicular deployment enables capture of solar radiation from additional angles, increasing the overall power generation capacity of the system. The first side bifacial photovoltaic panel 702 and second side bifacial photovoltaic panel 704 are constructed with the same specifications as the other photovoltaic panels, e.g., each rated at 400 watts and utilizing monocrystalline silicon with bifacial technology. The microcontroller 166 may be configured to control the operation of both sliding mechanisms 146, 706 based on solar radiation intensity signals to optimize the positioning of all photovoltaic panels for maximum solar energy capture.

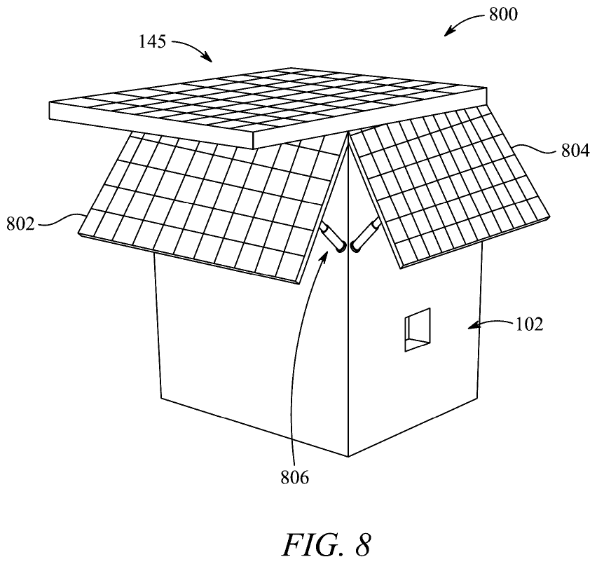

Referring to FIG. 8, illustrated is an exemplary perspective view of a solar photovoltaic-powered thermoelectric system 800 showing another alternative configuration with additional angled photovoltaic panels. In this configuration, the fixed bifacial photovoltaic panel 150 is mounted horizontally on the cabinet 102. A first angled bifacial photovoltaic panel 802 and a second angled bifacial photovoltaic panel 804 are connected to opposing sides of the cabinet 102 using linear actuators 806 implemented as hydraulic jacks. The linear actuators 806 are configured to deploy the first angled bifacial photovoltaic panel 802 and the second angled bifacial photovoltaic panel 804 at adjustable angles relative to the walls of the cabinet 102. This angular deployment enables capture of solar radiation during different times of day as the position of the sun changes, thereby maximizing the duration of effective solar energy collection. The first angled bifacial photovoltaic panel 802 and the second angled bifacial photovoltaic panel 804 may be constructed with the same specifications as the fixed bifacial photovoltaic panel 150, e.g., each rated at 400 watts and utilizing monocrystalline silicon with bifacial technology. The microcontroller 166 may be configured to control the operation of the linear actuators 806 based on solar radiation intensity signals to adjust the deployment angles of the photovoltaic panels 802, 804 for optimal solar energy capture throughout the day. This configuration enables the solar photovoltaic-powered thermoelectric system 100 to maintain efficient power generation across a wider range of sun angles compared to fixed-angle installations.

Referring now to FIG. 9, the present disclosure further provides a method (as represented by a flowchart, referred by reference numeral 900) for using the solar photovoltaic-powered thermoelectric system 100 to cool air. The method 900 includes a series of steps. These steps are only illustrative, and other alternatives may be considered where one or more steps are added, one or more steps are removed, or one or more steps are provided in a different sequence without departing from the scope of the present disclosure. Various variants disclosed above, with respect to the aforementioned solar photovoltaic-powered thermoelectric system 100 apply mutatis mutandis to the present method 900 for using it to cool air.

At step 902, the method 900 includes turning ON the solar photovoltaic-powered thermoelectric system 100. The solar photovoltaic-powered thermoelectric system 100 is activated using either the ON/OFF button, as accessible through the oval cutout 103c in the access door 103 of the cabinet 102, or through a remote control mechanism. The activation initiates power flow from the at least one rechargeable battery 162 and begins the operation of the microcontroller 166.

At step 904, the method 900 includes providing power from the at least one rechargeable battery 162 located in the lower compartment 106 of the cabinet 102 to the plurality of intake air fans 114 located within the intake fan openings 110 in the first wall 102a of the cabinet 102. Herein, the plurality of intake air fans 114 are configured to draw ambient air into the upper compartment 104 of the cabinet 102. The microcontroller 166 regulates the power supply 172 to operate the intake air fans 114 at speeds up to 220 cubic feet per minute. The intake air fans 114 draw ambient air through the air vents 120 of the intake housing 116, which are configured as rectangular openings measuring approximately 25 millimeters by 100 millimeters and arranged in five vertical rows.

At step 906, the method 900 includes providing a DC current to the plurality of thermoelectric modules 140 mounted on the panel 142 located at a center of the cabinet 102, in which the panel 142 is configured to divide the upper compartment 104 of the cabinet 102 into a hot side and a cold side. The panel 142, constructed of polymethyl methacrylate material, extends vertically across the upper compartment 104. The DC current is supplied from the at least one rechargeable battery 162 through electrical connections controlled by the microcontroller 166 to power the thermoelectric modules 140.

At step 908, the method 900 includes generating, by the DC current, a heated surface on each of the plurality of thermoelectric modules 140 on the hot side 140a and a cooled surface on each of the plurality of thermoelectric modules 140 on the cold side 140b. When the DC current passes through the thermoelectric modules 140, the Peltier effect creates a temperature differential, with the hot side 140a absorbing heat and the cold side 140b releasing heat. The heat sink 118 of each intake air fan 114 is mounted with thermal paste to the hot side 140a, while the heat sink 126 of each outtake cooling fan 122 is mounted with thermal paste to the cold side 140b, facilitating efficient heat transfer.

At step 910, the method 900 includes providing the DC current to the plurality of outtake cooling fans 122 located within the outtake fan openings 112 in the second wall 102b of the cabinet 102. Herein, the plurality of outtake cooling fans 122 are configured to draw cooled air from the cold side and expel the cooled air through the air duct 138 covering the plurality of outtake fan openings 112. The outtake cooling fans 122 operate at speeds up to 360 cubic feet per minute, drawing air through the air vents 128 of the outtake housing 124. The cooled air is then expelled through the outtake port 136 of the outtake fan cover 134 into the air duct 138, which directs the cooled air to the desired location in the enclosed area.

At step 912, the method 900 includes generating, by the plurality of sensors 164, a plurality of measurement signals. The temperature sensor monitors ambient temperature and temperature differentials across the thermoelectric modules 140, the relative humidity sensor measures moisture content in the air, and the solar radiation intensity sensor measures the intensity and angle of incident sunlight. These measurement signals are continuously transmitted to the microcontroller 166 for processing.

At step 914, the method 900 includes actuating, by the microcontroller 166 including electrical circuitry, a memory storing program instructions including a load sensing program, and at least one processor configured to execute the program instructions and analyze the plurality of measurement signals based on the load sensing program, a motor (not shown) of the sliding mechanism 146 connected to the exterior face of the top surface 102e of the cabinet 102. Herein, the sliding mechanism 146 is connected by the linear actuator 148 to the fixed bifacial photovoltaic panel 150, the first sliding bifacial photovoltaic panel 152 and the second sliding bifacial photovoltaic panel 154 located below the fixed bifacial photovoltaic panel 150. Based on the measurement signals from the plurality of sensors 164, the microcontroller 166 executes the load sensing program to determine optimal panel positions. The motor operates the linear actuator 148 at approximately 10 millimeters per second through its 170-millimeter stroke length, with integrated Hall effect sensor providing position feedback for precise control.

At step 916, the method 900 includes generating, during daylight hours, a DC electrical current with the fixed bifacial photovoltaic panel 150, the first sliding bifacial photovoltaic panel 152 and the second sliding bifacial photovoltaic panel 154. Each photovoltaic panel, rated at 400 watts and constructed using monocrystalline silicon with bifacial technology, generates power from both front and rear surfaces. The panels operate with a rated voltage of 20 volts and a rated current of 10.5 amperes at maximum power point, with an open circuit voltage of 24.5 volts and a short circuit current of 12.5 amperes. The reflective layer 156 positioned beneath the sliding mechanism 146 enhances power generation by redirecting sunlight to the rear surfaces of the panels.

At step 918, the method 900 includes recharging the at least one rechargeable battery 162 with the DC electrical current. The inverter 160 converts the variable DC power from the photovoltaic panels into stable DC current suitable for charging the 200 ampere-hour batteries. The microcontroller 166 manages the charging process, implementing protective features such as overcharge protection and thermal protection to ensure safe and efficient battery charging operation.

It may be appreciated that the above steps 902-918 may operate continuously and simultaneously during operation of the solar photovoltaic-powered thermoelectric system 100. The microcontroller 166 constantly monitors the measurement signals from the plurality of sensors 164 and adjusts the operation of various components accordingly to maintain optimal cooling performance. For example, while steps 904-910 maintain the cooling operation using power from the at least one rechargeable battery 162, steps 914-918 simultaneously manage solar power generation and battery charging to ensure continuous power availability.

The method 900 further includes cleaning, by the plurality of self-cleaning brushes 158 located on the sliding mechanism 146, a surface of the first sliding bifacial photovoltaic panel 152 and a surface of the second sliding bifacial photovoltaic panel 154 as the first sliding bifacial photovoltaic panel 152 and the second sliding bifacial photovoltaic panel 154 slide past the plurality of self-cleaning brushes 158. The cleaning operation occurs when the linear actuator 148 moves the panels 152, 154 horizontally beneath the fixed bifacial photovoltaic panel 150. The plurality of self-cleaning brushes 158, mounted at corners of the fixed bifacial photovoltaic panel 150, engage with surfaces of the panels 152, 154 during this movement to remove accumulated dust and debris. This cleaning action takes place before the panels overlap in their final position, ensuring clean surfaces for optimal solar energy capture during subsequent operation. This self-cleaning mechanism operates automatically as part of the panel positioning process controlled by the microcontroller 166, requiring no additional user intervention.

The method 900 further includes generating the measurement signals by at least one temperature sensor, at least one relative humidity sensor and at least one solar radiation intensity sensor of the plurality of sensors 164. The temperature sensor continuously monitors ambient temperature and temperature differentials across the thermoelectric modules 140, providing temperature signals to the microcontroller 166 to optimize the cooling process. The relative humidity sensor measures the moisture content in the air before and after it passes through the cooling system, generating relative humidity signals that enable the microcontroller 166 to monitor the dehumidification effect of the cooling process. The solar radiation intensity sensor measures both the intensity and angle of incident sunlight throughout operation, producing solar radiation intensity signals that allow the microcontroller 166 to determine optimal positioning of the photovoltaic panels. These measurement signals are continuously generated and transmitted to the microcontroller 166, where they are processed by the load sensing program to make real-time adjustments to system operations, including fan speeds, thermoelectric module power levels, and panel positions.

The method 900 further includes establishing operational connections in which the microcontroller 166 is operatively connected to: the at least one rechargeable battery 162 for power management; the plurality of intake air fans 114 and the plurality of outtake cooling fans 122 for airflow control; the fixed bifacial photovoltaic panel 150, the first sliding bifacial photovoltaic panel 152, and the second sliding bifacial photovoltaic panel 154 for power generation monitoring; the plurality of thermoelectric modules 140 for cooling control; the plurality of sensors 164 for environmental monitoring; and the motor of the sliding mechanism 146 for panel positioning. These connections enable comprehensive control and coordination of all system components by the microcontroller 166.

The method 900 includes charging the at least one rechargeable battery 162 with the DC current generated by the inverter 160 connected to the fixed bifacial photovoltaic panel 150, the first sliding bifacial photovoltaic panel 152 and the second sliding bifacial photovoltaic panel 154 based on the load sensing program. The inverter 160 receives power from the fixed bifacial photovoltaic panel 150, the first sliding bifacial photovoltaic panel 152, and the second sliding bifacial photovoltaic panel 154, which together can provide up to 4800 watts of input power. The inverter 160 converts the variable DC power from the photovoltaic panels into stable DC current suitable for charging the 200 ampere-hour batteries. Based on the load sensing program, the microcontroller 166 regulates the charging process, implementing protective features such as overcharge protection and thermal protection.

The method 900 also includes providing the current from the at least one rechargeable battery 162 to the plurality of thermoelectric modules 140. The microcontroller 166 regulates the current supply based on temperature signals from the plurality of sensors 164 to maintain optimal temperature differentials across the thermoelectric modules 140. This controlled current flow enables efficient operation of the Peltier effect, where the hot side 140a of each thermoelectric module 140 absorbs heat while the cold side 140b releases heat. The method 900 further includes actuating the plurality of intake air fans 114. The microcontroller 166 controls the operation speed of the intake air fans 114 up to 220 cubic feet per minute based on temperature signals and cooling requirements. The intake air fans 114 draw ambient air through the air vents 120, which passes over the heat sink 118 mounted to the hot side 140a of the thermoelectric modules 140, where heat is absorbed before being expelled through the air vents 120. The method 900 further includes actuating the plurality of outtake cooling fans 122. The microcontroller 166 operates the outtake cooling fans 122 at speeds up to 360 cubic feet per minute based on temperature and humidity signals. The outtake cooling fans 122 draw air that has been cooled by the cold side 140b of the thermoelectric modules 140 through the air vents 128 of the outtake housing 124. The cooled and dehumidified air is then expelled through the outtake openings 112 into the air duct 138, which directs the conditioned air to the desired location within the enclosed area.

The method 900 further includes turning ON the solar photovoltaic-powered thermoelectric system 100 with a remote controller (not shown). The remote controller sends wireless activation signals to the microcontroller 166 through a receiver interface, providing an alternative to manual activation through the ON/OFF button accessible via the oval cutout 103c in the access door 103. When the remote controller signal is received, the microcontroller 166 initiates a startup sequence that includes: verifying the charge state of the at least one rechargeable battery 162, checking the status of all connected components through the electrical circuitry, and beginning the execution of stored program instructions. The remote control mechanism enables convenient system activation from a distance, particularly useful when the solar photovoltaic-powered thermoelectric system 100 is installed in locations where direct access to the cabinet 102 is limited or impractical. The microcontroller 166 confirms successful system activation by initiating operation of the cooling components and panel positioning system according to the current environmental conditions detected by the plurality of sensors 164.

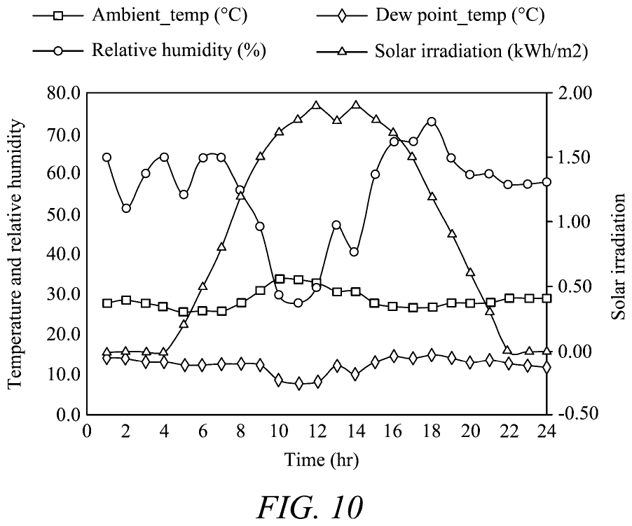

Tests were conducted on the solar photovoltaic-powered thermoelectric system 100 to evaluate cooling performance and operational efficiency. Initial testing demonstrated a peak cooling capacity between 6500-7000 BTU/hr. Testing was performed in Dhahran, Eastern Province of Saudi Arabia, under typical regional climatic conditions. Referring to FIG. 10, illustrated is a graph representing characteristics of a testing environment for the solar photovoltaic-powered thermoelectric system 100 over a period of time. Specifically, as shown, the testing environment exhibited the following characteristics over a 24-hour period: ambient temperature maintained between 25-35° C., dew point temperature remained stable at approximately 12° C., relative humidity varied between 30-70%, and solar irradiation peaked at 1.8 kW/m² during midday hours.

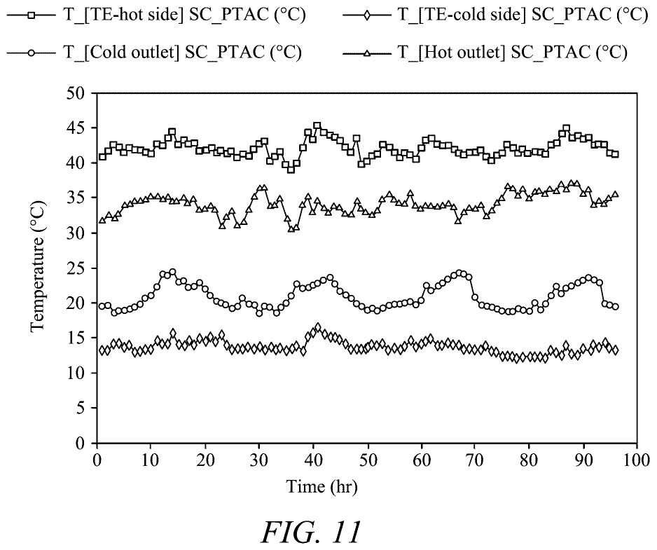

Referring to FIG. 11, illustrated is a graph representing temperature measurements recorded at multiple points within the solar photovoltaic-powered thermoelectric system 100 over a 96-hour period. The temperature at the hot side 140a of the thermoelectric modules 140 and associated heat sink 118 maintained consistent elevated temperatures throughout the operational period, as indicated by T_[TE-hot side]SC_PTAC measurements. Values fluctuated between 40-45° C., demonstrating stable heat generation by the thermoelectric modules 140 when supplied with electrical current.

The temperature at the cold side 140b of the thermoelectric modules 140 and associated heat sink 126, represented by T_[TE-cold side]SC_PTAC measurements, remained consistently low, fluctuating between 10-20° C. This temperature differential was achieved through the Peltier effect, wherein the cold side 140b absorbed heat from the surrounding air. The air temperature exiting through the air duct 138, shown by T_[Cold outlet]SC_PTAC measurements, maintained a steady range between 15-25° C., demonstrating effective cooling of air before delivery to the conditioned space.

The temperature of air exiting through the intake fan openings 110, indicated by T_[Hot outlet]SC_PTAC measurements in FIG. 11, fluctuated between 30-40° C., remaining below the temperature at the hot side 140a. This temperature differential indicated effective heat dissipation through the heat sinks 118, 126 and the plurality of intake air fans 114 and plurality of outtake cooling fans 122, preventing excessive thermal accumulation within the solar photovoltaic-powered thermoelectric system 100.

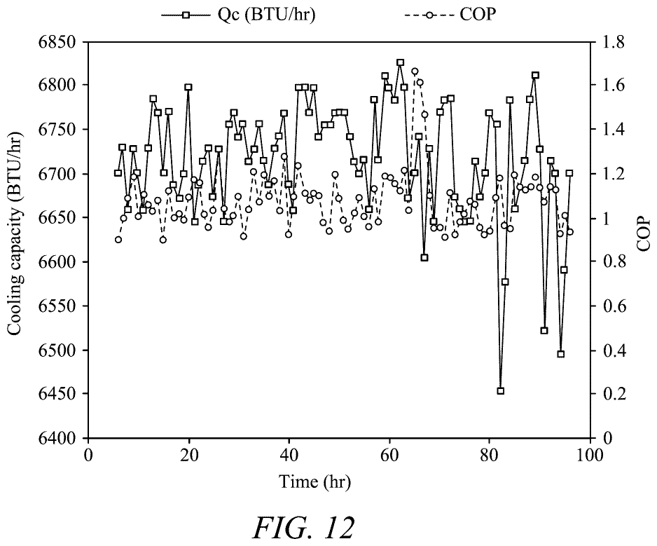

Referring to FIG. 12, illustrated is a graph representing a relationship between Coefficient of Performance (COP) and cooling capacity (Qc) for the solar photovoltaic-powered thermoelectric system 100. Herein, the relationship between COP and Qc was analyzed during continuous operation of the solar photovoltaic-powered thermoelectric system 100 over a 96-hour period. The thermoelectric modules 140 operated based on the Peltier effect, wherein electrical current created a temperature differential, with the cold side 140b absorbing heat while the hot side 140a released heat. The cold side 140b and associated heat sink 126 absorbed heat from ambient air, which was then transferred to the hot side 140a and dissipated through heat sink 118 into the environment. The plurality of intake air fans 114 and plurality of outtake cooling fans 122 enhanced this heat transfer process by circulating air across the respective heat sinks.

The cooling capacity measurements demonstrated fluctuation between 6400-6850 BTU/hr in response to varying thermal loads. Higher cooling capacities were recorded during daytime operation due to increased ambient temperatures and occupancy levels. During nighttime periods, when ambient temperatures and occupancy decreased, the solar photovoltaic-powered thermoelectric system 100 operated at reduced capacity while maintaining efficiency. The at least one rechargeable battery 162 supplied power during these periods, having stored excess energy generated by the fixed bifacial photovoltaic panel 150, the first sliding bifacial photovoltaic panel 152, and the second sliding bifacial photovoltaic panel 154 during peak sunlight hours.

The COP measurements indicated values between 0.8 and 1.4, varying in relation to cooling load and power consumption. Lower COP values corresponded to periods of high cooling demand when increased power was required from the at least one rechargeable battery 162 to drive the thermoelectric modules 140. Higher COP values were achieved during periods of reduced cooling demand, particularly during nighttime operation. The measured performance parameters demonstrated the ability of the solar photovoltaic-powered thermoelectric system 100 to maintain net-zero energy operation by utilizing stored solar energy during periods of low solar radiation, while adapting to varying environmental conditions and cooling demands.

The solar photovoltaic-powered thermoelectric system 100 and the method 900 of the present disclosure provide a comprehensive solution for net-zero cooling by integrating solar power generation with thermoelectric cooling principles. The solar photovoltaic-powered thermoelectric system 100 incorporates the sliding mechanism 146 that enables horizontal movement of the first sliding bifacial photovoltaic panel 152 and the second sliding bifacial photovoltaic panel 154 beneath the fixed bifacial photovoltaic panel 150, while the plurality of self-cleaning brushes 158 maintain panel surfaces during this movement. The microcontroller 166 coordinates operation of the sliding mechanism 146 based on measurement signals from the plurality of sensors 164, enabling optimal positioning of the photovoltaic panels for maximum solar energy capture. The thermoelectric modules 140, mounted on the panel 142 between intake air fans 114 and outtake cooling fans 122, provide efficient cooling without requiring traditional refrigerants or compressors.

The solar photovoltaic-powered thermoelectric system 100 offers significant operational benefits through multiple features. The sliding mechanism 146 with integrated self-cleaning capability eliminates manual cleaning requirements while maintaining optimal energy generation efficiency. The bifacial technology of the photovoltaic panels 150, 152, 154, combined with the reflective layer 156, increases solar energy capture from both direct and reflected sunlight. The thermoelectric cooling mechanism eliminates the need for refrigerants and mechanical compressors, reducing maintenance requirements and environmental impact. The at least one rechargeable battery 162 enables continuous operation during periods of low solar radiation, while the microcontroller 166 optimizes system performance through real-time monitoring and adjustment based on environmental conditions detected by the plurality of sensors 164. The portable configuration with the plurality of wheels 109 enables flexible deployment, while the thermal isolation between the upper compartment 104 and lower compartment 106 ensures efficient operation of both cooling and electrical components. The architecture of the solar photovoltaic-powered thermoelectric system 100 addresses key challenges in solar-powered cooling, including maintenance of power generation efficiency, optimization of heat transfer, and management of variable solar availability. The modular design of the solar photovoltaic-powered thermoelectric system 100 provides scaling of cooling capacity to meet various application requirements, while the portable configuration allows for flexible deployment across different locations.

A first embodiment describes a solar photovoltaic-powered thermoelectric system 100, comprising: a cabinet 102 including a first wall 102a, a second wall 102b, a third wall 102c, a fourth wall 102d, a top surface 102e and a bottom surface 102f; a plurality of intake air fans 114 located within intake fan openings 110 in the cabinet 102 which extend through the first wall 102a, wherein each intake air fan 114 is surrounded by an intake housing 116 having a heat sink 118 on a back surface 116a and a plurality of air vents 120 on a first side surface 116b and a second side surface 116c, wherein the second side surface 116c is opposite the first side surface 116b; a plurality of outtake cooling fans 122 located within outtake fan openings 112 in the cabinet 102 which extend through the second wall 102b, wherein the second wall 102b is opposite the first wall 102a, wherein each outtake cooling fan 122 is surrounded by an outtake housing 124 having a heat sink 126 on a back surface 124a and a plurality of air vents 128 on a first side surface 124b and a second side surface 124c, wherein the second side surface 124c is opposite the first side surface 124b; a plurality of thermoelectric modules 140 mounted on a panel 142 located at a center of the cabinet 102 between the plurality of back surfaces of the intake cooling fans 114 and the back surfaces of the outtake cooling fans 122; a sliding mechanism 146 connected to the exterior face of the top surface 102e; a fixed bifacial photovoltaic panel 150 connected to the sliding mechanism 146; a first sliding bifacial photovoltaic panel 152 and a second sliding bifacial photovoltaic panel 154 connected to the sliding mechanism 146 below the fixed photovoltaic panel 150; an inverter 160 operatively connected to the fixed bifacial photovoltaic panel 150, the first sliding bifacial photovoltaic panel 152 and the second sliding bifacial photovoltaic panel 154, wherein the inverter 160 is configured to generate a DC current from power generated by the fixed bifacial photovoltaic panel 150, the first sliding bifacial photovoltaic panel 152 and the second sliding bifacial photovoltaic panel 154; at least one rechargeable battery 162 located on the bottom surface 102f, wherein the at least one rechargeable battery 162 is operatively connected to store the DC current from the inverter 160 in a charging cycle; a plurality of sensors 164 located within the cabinet 102; a microcontroller 166 connected to the at least one rechargeable battery 162, the inverter 160, the plurality of intake cooling fans 114, the plurality of outtake cooling fans 122, the fixed bifacial photovoltaic panel 150, the first sliding bifacial photovoltaic panel 152, the second sliding bifacial photovoltaic panel 154, the plurality of thermoelectric modules 140, the plurality of sensors 164 and the sliding mechanism 146, wherein the microcontroller 166 includes electrical circuitry, a memory storing program instructions and at least one processor configured to execute the program instructions to receive measurement signals from the plurality of sensors 164, and based on the measurement signals: actuate the sliding mechanism 146 to position the first sliding bifacial photovoltaic panel 152 and the second sliding bifacial photovoltaic panel 154 to receive maximum solar radiation; charge the at least one rechargeable battery 162 with the DC electricity generated by the inverter 160; provide the DC electrical current from the rechargeable battery 162 to the thermoelectric modules 140; actuate the plurality of intake cooling fans 114 to draw ambient air towards the heat sink 118 on the back surface and expel heated air through the plurality of air vents 120 of the intake housing 116; and actuate the plurality of outtake cooling fans 122 to draw a cooled air through the plurality of air vents 128 of the outtake housing 124 and expel the cooled air through the plurality of outtake openings 112 in the second wall 102b of the cabinet 102, wherein the plurality of outtake openings 112 are connected to an air duct 138 configured to convey the cooled air into an enclosed area.

In an aspect, the solar photovoltaic-powered thermoelectric system 100, further comprises: a plurality of self-cleaning brushes 158 located on the sliding mechanism 146, wherein the plurality of cleaning brushes 158 are configured to brush a surface of the first sliding bifacial photovoltaic panel 152 and a surface of the second sliding bifacial photovoltaic panel 154 as the first sliding bifacial photovoltaic panel 152 and the second sliding bifacial photovoltaic panel 154 slide past the plurality of self-cleaning brushes 158.

In an aspect, the solar photovoltaic-powered thermoelectric system 100, further comprises: an access door 103 located on a third wall 102c of the cabinet 102, wherein the third wall 102c is perpendicular to the first wall 102a and the second wall 102b.

In an aspect, the access door 103 comprises an access port cutout 103a, a key lock 103b and an oval cutout 103c configured to provide access to an ON/OFF button operatively connected to the microcontroller 166.

In an aspect, the solar photovoltaic-powered thermoelectric system 100, further comprises: a plurality of wheels 109 located on an exterior of the bottom surface 102f, wherein each of the plurality of wheels 109 are configured with a locking mechanism.

In an aspect, the cabinet 102 is configured with an upper compartment 104 adjacent the top surface 102e, a lower compartment 106 adjacent the bottom surface 102f, and a divider shelf 108 located between the upper compartment 104 and the lower compartment 106, the plurality of intake cooling fans 114, the plurality of outtake cooling fans 122, the openings 110 in the first wall 102a, the openings 112 in the second wall 102b and the panel 142 are located in the upper compartment 104, and the at least one rechargeable battery 162 is located in the lower compartment 106.

In an aspect, the solar photovoltaic-powered thermoelectric system 100, further comprises a drain port 144 located in the upper compartment 104 on the second wall 102b adjacent to the divider shelf 108, wherein the drain port 144 is connected to a drain line configured to convey condensed water from the cabinet 102.

In an aspect, the solar photovoltaic-powered thermoelectric system 100, further comprises a reflective layer 156 configured to cover an exterior face of the top surface 102e of the cabinet 102.

In an aspect, the cabinet 102 is made of aluminum.

In an aspect, the heat sink 118 of each intake air fan 114 is mounted with a thermal paste to a hot side 140a of one of the plurality of thermoelectric modules 140, and the heat sink 126 of each outtake cooling fan 122 is mounted with the thermal paste to a cold side 140b of one of the plurality of thermoelectric modules 140.

In an aspect, the solar photovoltaic-powered thermoelectric system 100, further comprises: an intake fan cover 130 located over each intake fan opening 110, wherein the intake fan cover 130 is configured with louvered vents 132; and an outtake fan cover 134 located over each outtake fan opening 112, wherein the outtake fan cover 134 includes an outtake port 136 configured to receive the air duct 138.

In an aspect, the plurality of thermoelectric modules 140 are configured to cool and dehumidify the ambient air drawn into the cabinet 102 by the plurality of intake cooling fans 114, and the plurality of outtake cooling fans 122 are configured to exhaust the cooled and dehumidified air from the cabinet 102 through the air duct 138.

In an aspect, the microcontroller 166 is further configured to: receive temperature signals, relative humidity signals and solar radiation intensity signals from the plurality of sensors 164, and based on the temperature signals, the relative humidity signals and the solar radiation intensity signals: actuate the sliding mechanism 146 to position the first sliding bifacial photovoltaic panel 152 and the second sliding bifacial photovoltaic panel 154 to receive maximum solar radiation; charge the at least one rechargeable battery 162 with the DC electricity generated by the inverter 160; provide the DC electrical current from the rechargeable battery 162 to the plurality of thermoelectric modules 140; actuate the plurality of intake cooling fans 114 to draw ambient air towards the heat sink 118 on the back surface and expel heated air through the plurality of air vents 120 of the intake housing 116; and actuate the plurality of outtake cooling fans 122 to draw a cooled air through the plurality of air vents 128 of the outtake housing 124 and expel the cooled air through the plurality of outtake openings 112 in the second wall 102b of the cabinet 102, wherein the plurality of outtake openings 112 are connected to an air duct 138 configured to convey the cooled air into an enclosed area.

In an aspect, the microcontroller 166 is further configured to: receive the temperature signals, the relative humidity signals and the solar radiation intensity signals from the plurality of sensors 164, and based on the temperature signals, the relative humidity signals and the solar radiation intensity signals: actuate the plurality of self-cleaning brushes 158 to clean a surface of the first sliding bifacial photovoltaic panel 152 and a surface of the second sliding bifacial photovoltaic panel 154.

A second embodiment describes a method 900 of cooling and dehumidifying air for providing thermal comfort in an enclosed area, comprising: turning ON the solar photovoltaic-powered thermoelectric system 100; providing power from the at least one rechargeable battery 162 located in the lower compartment 106 of the cabinet 102 surrounding the solar photovoltaic-powered thermoelectric system 100 to the plurality of intake cooling fans 114 located within the upper compartment 104 of the cabinet 102, wherein the upper compartment 104 is above the lower compartment 106; drawing ambient air into the cabinet 102 through the plurality of intake fan openings 110 extending through the first wall 102a with the plurality of intake cooling fans 114; passing the ambient air over a hot side 140a of the plurality of thermoelectric modules 140 mounted on the panel 142 located at a center of the cabinet 102, wherein the panel 142 divides the upper compartment 104 into a hot zone adjacent to the first wall 102a and a cold zone adjacent to the second wall 102b; drawing the ambient air across the hot side 140a of the plurality of thermoelectric modules 140 with the plurality of intake cooling fans 114; passing the ambient air through a plurality of air vents 120 in an intake housing 116 surrounding each of the plurality of intake cooling fans 114, wherein the plurality of air vents 120 are positioned on a first side surface 116b and a second side surface 116c of the intake housing 116, wherein the second side surface 116c is opposite the first side surface 116b; expelling the ambient air from the cabinet 102 through the plurality of air vents 120; drawing a cooled air across a cold side 140b of the plurality of thermoelectric modules 140 with the plurality of outtake cooling fans 122 located within the upper compartment 104 of the cabinet 102; passing the cooled air through a plurality of air vents 128 in an outtake housing 124 surrounding each of the plurality of outtake cooling fans 122, wherein the plurality of air vents 128 are positioned on a first side surface 124b and a second side surface 124c of the outtake housing 124, wherein the second side surface 124c is opposite the first side surface 124b; expelling the cooled air from the cabinet 102 through the plurality of outtake openings 112 extending through the second wall 102b, wherein the second wall 102b is opposite the first wall 102a; and conveying the cooled air into the enclosed area with the air duct 138.

In an aspect, the method 900, further comprises: receiving measurement signals by the microcontroller 166 from the plurality of sensors 164 located within the cabinet 102; and based on the measurement signals: actuating, by the microcontroller 166, a motor of the sliding mechanism 146 to position a first sliding bifacial photovoltaic panel 152 and a second sliding bifacial photovoltaic panel 154 located below a fixed photovoltaic panel 150 to receive maximum solar radiation.

In an aspect, the method 900, further comprises: brushing a surface of the first sliding bifacial photovoltaic panel 152 and a surface of the second sliding bifacial photovoltaic panel 154 with a plurality of self-cleaning brushes 158 as the first sliding bifacial photovoltaic panel 152 and the second sliding bifacial photovoltaic panel 154 slide past the plurality of self-cleaning brushes 158.

In an aspect, the method 900, further comprises: generating the measurement signals by at least one temperature sensor, at least one relative humidity sensor and at least one solar radiation intensity sensor of the plurality of sensors 164.

In an aspect, the microcontroller 166 is operatively connected to the rechargeable battery 162, the plurality of intake cooling fans 114, the plurality of outtake cooling fans 122, the fixed bifacial photovoltaic panel 150, the first sliding bifacial photovoltaic panel 152, the second sliding bifacial photovoltaic panel 154, the plurality of thermoelectric modules 140, the plurality of sensors 164 and the motor of the sliding mechanism 146, wherein the at least one processor is further configured to execute the program instructions for: charging the rechargeable battery 162 with the DC current generated by an inverter 160 connected to the fixed bifacial photovoltaic panel 150, the first sliding bifacial photovoltaic panel 152 and the second sliding bifacial photovoltaic panel 154 based on the load sensing program; providing the current from the rechargeable battery 162 to the plurality of thermoelectric modules 140; actuating the plurality of intake cooling fans 114; and actuating the plurality of outtake cooling fans 122.

In an aspect, the method 900, further comprises: turning ON the solar photovoltaic-powered thermoelectric system 100 with a remote controller.

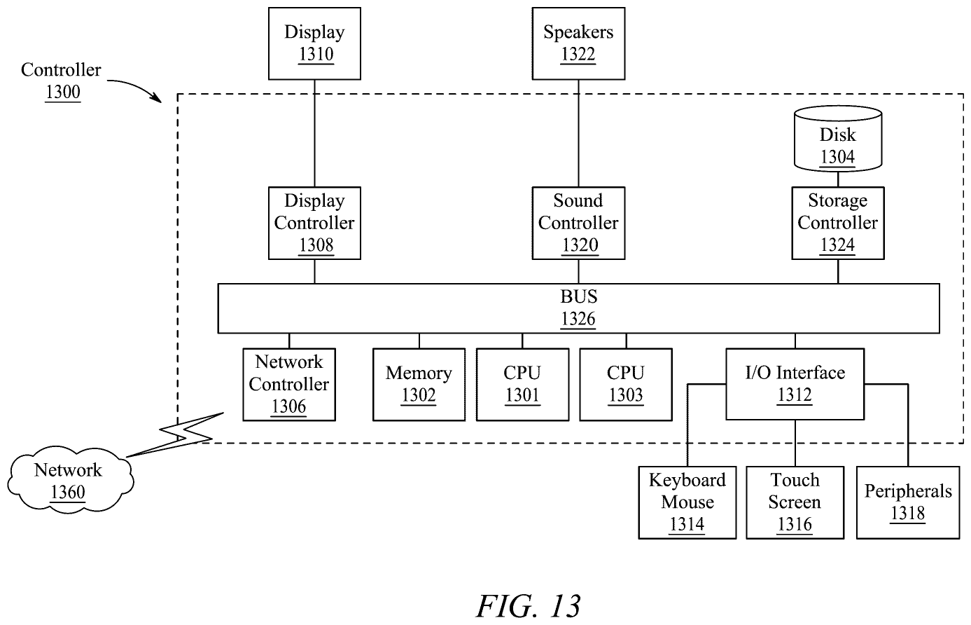

Next, further details of the hardware description of a computing environment according to exemplary embodiments is described with reference to FIG. 13. In FIG. 13, a controller 1300 is described is representative of the microcontroller 166 of the solar photovoltaic-powered thermoelectric system 100, in which the controller 1300 is a computing device which includes a CPU 1301 which performs the processes described above/below. The process data and instructions may be stored in memory 1302. These processes and instructions may also be stored on a storage medium disk 1304 such as a hard drive (HDD) or portable storage medium or may be stored remotely.

Further, the claims are not limited by the form of the computer-readable media on which the instructions of the inventive process are stored. For example, the instructions may be stored on CDs, DVDs, in FLASH memory, RAM, ROM, PROM, EPROM, EEPROM, hard disk or any other information processing device with which the computing device communicates, such as a server or computer.

Further, the claims may be provided as a utility application, background daemon, or component of an operating system, or combination thereof, executing in conjunction with CPU 1301, 1303 and an operating system such as Microsoft Windows 7, Microsoft Windows 8, Microsoft Windows 10, UNIX, Solaris, LINUX, Apple MAC-OS and other systems known to those skilled in the art.

The hardware elements in order to achieve the computing device may be realized by various circuitry elements, known to those skilled in the art. For example, CPU 1301 or CPU 1303 may be a Xenon or Core processor from Intel of America or an Opteron processor from AMD of America, or may be other processor types that would be recognized by one of ordinary skill in the art. Alternatively, the CPU 1301, 1303 may be implemented on an FPGA, ASIC, PLD or using discrete logic circuits, as one of ordinary skill in the art would recognize. Further, CPU 1301, 1303 may be implemented as multiple processors cooperatively working in parallel to perform the instructions of the inventive processes described above.

The computing device in FIG. 13 also includes a network controller 1306, such as an Intel Ethernet PRO network interface card from Intel Corporation of America, for interfacing with network 1360. As can be appreciated, the network 1360 can be a public network, such as the Internet, or a private network such as an LAN or WAN network, or any combination thereof and can also include PSTN or ISDN sub-networks. The network 1360 can also be wired, such as an Ethernet network, or can be wireless such as a cellular network including EDGE, 3G, 4G and 5G wireless cellular systems. The wireless network can also be WiFi, Bluetooth, or any other wireless form of communication that is known.

The computing device further includes a display controller 1308, such as a NVIDIA GeForce GTX or Quadro graphics adaptor from NVIDIA Corporation of America for interfacing with display 1310, such as a Hewlett Packard HPL2445w LCD monitor. A general purpose I/O interface 1312 interfaces with a keyboard and/or mouse 1314 as well as a touch screen panel 1316 on or separate from display 1310. General purpose I/O interface also connects to a variety of peripherals 1318 including printers and scanners, such as an OfficeJet or DeskJet from Hewlett Packard.

A sound controller 1320 is also provided in the computing device such as Sound Blaster X-Fi Titanium from Creative, to interface with speakers/microphone 1322 thereby providing sounds and/or music.

The general purpose storage controller 1324 connects the storage medium disk 1304 with communication bus 1326, which may be an ISA, EISA, VESA, PCI, or similar, for interconnecting all of the components of the computing device. A description of the general features and functionality of the display 1310, keyboard and/or mouse 1314, as well as the display controller 1308, storage controller 1324, network controller 1306, sound controller 1320, and general purpose I/O interface 1312 is omitted herein for brevity as these features are known.

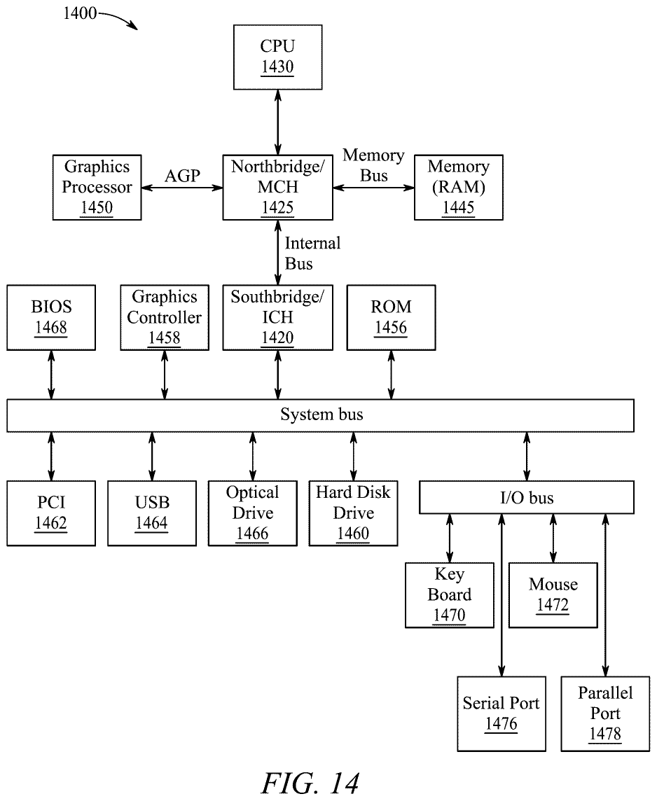

The exemplary circuit elements described in the context of the present disclosure may be replaced with other elements and structured differently than the examples provided herein. Moreover, circuitry configured to perform features described herein may be implemented in multiple circuit units (e.g., chips), or the features may be combined in circuitry on a single chipset, as shown on FIG. 14.

FIG. 14 shows a schematic diagram of a data processing system, according to certain embodiments, for performing the functions of the exemplary embodiments. The data processing system is an example of a computer in which code or instructions implementing the processes of the illustrative embodiments may be located.

In FIG. 14, data processing system 1400 employs a hub architecture including a north bridge and memory controller hub (NB/MCH) 1425 and a south bridge and input/output (I/O) controller hub (SB/ICH) 1420. The central processing unit (CPU) 1430 is connected to NB/MCH 1425. The NB/MCH 1425 also connects to the memory 1445 via a memory bus and connects to the graphics processor 1450 via an accelerated graphics port (AGP). The NB/MCH 1425 also connects to the SB/ICH 1420 via an internal bus (e.g., a unified media interface or a direct media interface). The CPU Processing unit 1430 may contain one or more processors and even may be implemented using one or more heterogeneous processor systems.

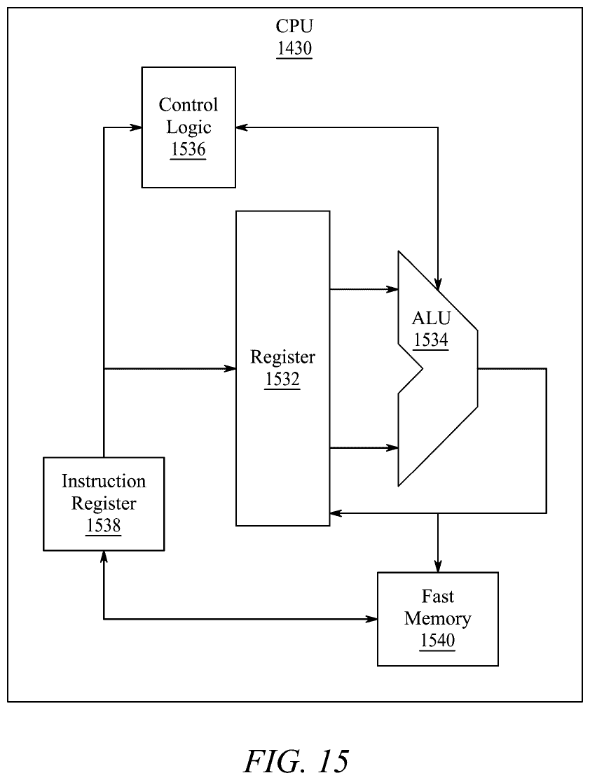

For example, FIG. 15 shows one implementation of CPU 1430. In one implementation, the instruction register 1538 retrieves instructions from the fast memory 1540. At least part of these instructions are fetched from the instruction register 1538 by the control logic 1536 and interpreted according to the instruction set architecture of the CPU 1430. Part of the instructions can also be directed to the register 1532. In one implementation the instructions are decoded according to a hardwired method, and in another implementation the instructions are decoded according a microprogram that translates instructions into sets of CPU configuration signals that are applied sequentially over multiple clock pulses. After fetching and decoding the instructions, the instructions are executed using the arithmetic logic unit (ALU) 1534 that loads values from the register 1532 and performs logical and mathematical operations on the loaded values according to the instructions. The results from these operations can be feedback into the register and/or stored in the fast memory 1540. According to certain implementations, the instruction set architecture of the CPU 1430 can use a reduced instruction set architecture, a complex instruction set architecture, a vector processor architecture, a very large instruction word architecture. Furthermore, the CPU 1430 can be based on the Von Neuman model or the Harvard model. The CPU 1430 can be a digital signal processor, an FPGA, an ASIC, a PLA, a PLD, or a CPLD. Further, the CPU 1430 can be an x86 processor by Intel or by AMD; an ARM processor, a Power architecture processor by, e.g., IBM; a SPARC architecture processor by Sun Microsystems or by Oracle; or other known CPU architecture.

Referring again to FIG. 14, the data processing system 1400 can include that the SB/ICH 1420 is coupled through a system bus to an I/O Bus, a read only memory (ROM) 1456, universal serial bus (USB) port 1464, a flash binary input/output system (BIOS) 1468, and a graphics controller 1458. PCI/PCIe devices can also be coupled to SB/ICH 1488 through a PCI bus 1462.

The PCI devices may include, for example, Ethernet adapters, add-in cards, and PC cards for notebook computers. The Hard disk drive 1460 and CD-ROM 1466 can use, for example, an integrated drive electronics (IDE) or serial advanced technology attachment (SATA) interface. In one implementation the I/O bus can include a super I/O (SIO) device.

Further, the hard disk drive (HDD) 1460 and optical drive 1466 can also be coupled to the SB/ICH 1420 through a system bus. In one implementation, a keyboard 1470, a mouse 1472, a parallel port 1478, and a serial port 1476 can be connected to the system bus through the I/O bus. Other peripherals and devices that can be connected to the SB/ICH 1420 using a mass storage controller such as SATA or PATA, an Ethernet port, an ISA bus, a LPC bridge, SMBus, a DMA controller, and an Audio Codec.

Moreover, the present disclosure is not limited to the specific circuit elements described herein, nor is the present disclosure limited to the specific sizing and classification of these elements. For example, the skilled artisan will appreciate that the circuitry described herein may be adapted based on changes on battery sizing and chemistry or based on the requirements of the intended back-up load to be powered.

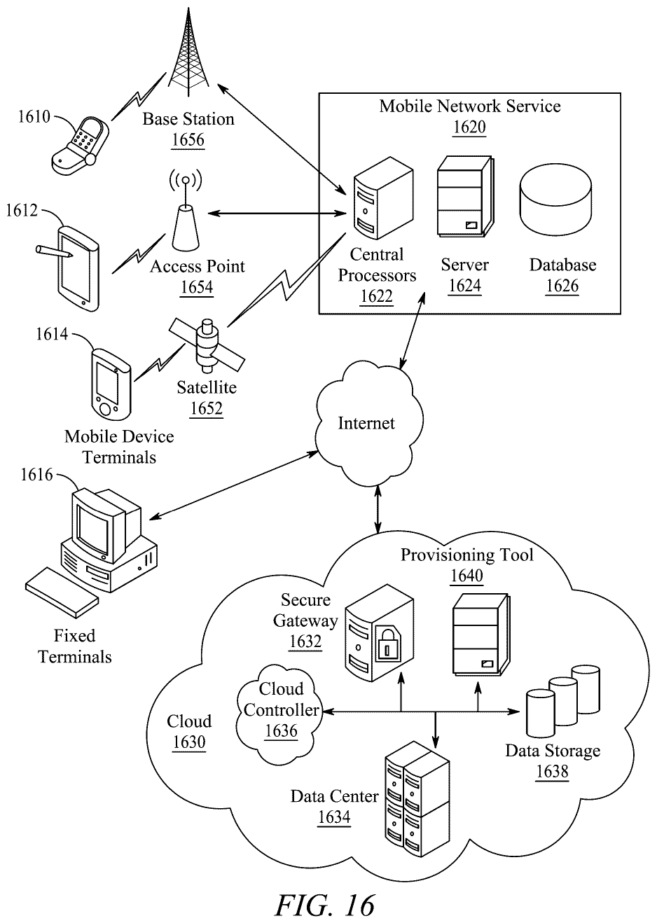

The functions and features described herein may also be executed by various distributed components of a system. For example, one or more processors may execute these system functions, wherein the processors are distributed across multiple components communicating in a network. The distributed components may include one or more client and server machines, such as cloud 1630 including a cloud controller 1636, a secure gateway 1632, a data center 1634, data storage 1638 and a provisioning tool 1640, and mobile network services 1620 including central processors 1622, a server 1624 and a database 1626, which may share processing, as shown by FIG. 16, in addition to various human interface and communication devices (e.g., display monitors 1616, smart phones 1610, tablets 1612, personal digital assistants (PDAs) 1614). The network may be a private network, such as a LAN, satellite 1652 or WAN 1654, or be a public network, may such as the Internet. Input to the system may be received via direct user input and received remotely either in real-time or as a batch process. Additionally, some implementations may be performed on modules or hardware not identical to those described. Accordingly, other implementations are within the scope that may be claimed.

While specific embodiments of the invention have been described, it should be understood that various modifications and alternatives may be implemented without departing from the spirit and scope of the invention. For example, different cellular automata rules or encryption algorithms could be employed, or alternative feature extraction and face recognition techniques could be integrated into the system.

The above-described hardware description is a non-limiting example of corresponding structure for performing the functionality described herein.

Numerous modifications and variations of the present disclosure are possible in light of the above teachings. It is therefore to be understood that within the scope of the appended claims, the invention may be practiced otherwise than as specifically described herein.

1. A solar photovoltaic-powered thermoelectric system, comprising:
a cabinet including a first wall, a second wall, a third wall, a fourth wall, a top surface and a bottom surface;
a plurality of intake air fans located within intake fan openings in the cabinet which extend through the first wall, wherein each intake air fan is surrounded by an intake housing having a heat sink on a back surface and a plurality of air vents on a first side surface and a second side surface, wherein the second side surface is opposite the first side surface;
a plurality of outtake cooling fans located within outtake fan openings in the cabinet which extend through the second wall, wherein the second wall is opposite the first wall, wherein each outtake cooling fan is surrounded by an outtake housing having a heat sink on a back surface and a plurality of air vents on a first side surface and a second side surface, wherein the second side surface is opposite the first side surface;
a plurality of thermoelectric modules mounted on a panel located at a center of the cabinet between the plurality of back surfaces of the intake cooling fans and the back surfaces of the outtake cooling fans;
a sliding mechanism connected to the exterior face of the top surface;
a fixed bifacial photovoltaic panel connected to the sliding mechanism;
a first sliding bifacial photovoltaic panel and a second sliding bifacial photovoltaic panel connected to the sliding mechanism below the fixed photovoltaic module;
an inverter operatively connected to the fixed bifacial photovoltaic panel, the first sliding bifacial photovoltaic panel and the second sliding bifacial photovoltaic panel, wherein the inverter is configured to generate a DC current from power generated by the fixed bifacial photovoltaic panel, the first sliding bifacial photovoltaic panel and the second sliding bifacial photovoltaic panel;
at least one rechargeable battery located on the bottom surface, wherein the at least one rechargeable battery is operatively connected to store the DC current from the inverter in a charging cycle;
a plurality of sensors located within the cabinet;
a microcontroller connected to the at least one rechargeable battery, the inverter, the plurality of intake cooling fans, the plurality of outtake cooling fans, the fixed bifacial photovoltaic panel, the first sliding bifacial photovoltaic panel, the second sliding bifacial photovoltaic panel, the plurality of thermoelectric modules, the plurality of sensors and the sliding mechanism, wherein the microcontroller includes electrical circuitry, a memory storing program instructions and at least one processor configured to execute the program instructions to receive measurement signals from the plurality of sensors, and based on the measurement signals:
actuate the sliding mechanism to position the first sliding bifacial photovoltaic panel and the second sliding bifacial photovoltaic panel to receive maximum solar radiation;
charge the at least one rechargeable battery with the DC electricity generated by the inverter;
provide the DC electrical current from the rechargeable battery to the thermoelectric module;
actuate the plurality of intake cooling fans to draw ambient air towards the heat sink on the back surface and expel heated air through the plurality of air vents of the intake housing; and
actuate the plurality of outtake cooling fans to draw a cooled air through the plurality of air vents of the outtake housing and expel the cooled air through the plurality of outtake openings in the second side of the cabinet, wherein the plurality of outtake openings are connected to an air duct configured to convey the cooled air into an enclosed area.

2. The solar photovoltaic-powered thermoelectric system of claim 1, further comprising:
a plurality of self-cleaning brushes located on the sliding mechanism, wherein the plurality of cleaning brushes are configured to brush a surface of the first sliding bifacial photovoltaic panel and a surface of the second sliding bifacial photovoltaic panel as the first sliding bifacial photovoltaic panel and the second sliding bifacial photovoltaic panel slide past the plurality of self-cleaning brushes.

3. The solar photovoltaic-powered thermoelectric system of claim 1, further comprising:
an access door located on a third wall of the cabinet, wherein the third wall is perpendicular to the first wall and the second wall.

4. The solar photovoltaic-powered thermoelectric system of claim 3, wherein the access door comprises an access port cutout, a key lock and an oval cutout configured to provide access to an ON/OFF button operatively connected to the microcontroller.

5. The solar photovoltaic-powered thermoelectric system of claim 1, further comprising:
a plurality of wheels located on an exterior of the bottom surface, wherein each of the plurality of wheels are configured with a locking mechanism.

6. The solar photovoltaic-powered thermoelectric system of claim 1, wherein:
the cabinet is configured with an upper compartment adjacent the top surface, a lower compartment adjacent the bottom surface, and a divider shelf located between the upper compartment and the lower compartment,
the plurality of intake cooling fans, the plurality of outtake cooling fans, the openings in the first wall, the openings in the second wall and the panel are located in the upper compartment, and
the at least one rechargeable battery is located in the lower compartment.

7. The solar photovoltaic-powered thermoelectric system of claim 6, further comprising a drain port located in the upper compartment on the second wall adjacent to the divider shelf, wherein the drain port is connected to a drain line configured to convey condensed water from the cabinet.

8. The solar photovoltaic-powered thermoelectric system of claim 1, further comprising a reflective layer configured to cover an exterior face of the top surface of the cabinet.

9. The solar photovoltaic-powered thermoelectric system of claim 1, wherein the cabinet is made of aluminum.

10. The solar photovoltaic-powered thermoelectric system of claim 1, wherein the panel is a polymethyl methacrylate sheet.

11. The solar photovoltaic-powered thermoelectric system of claim 10, wherein
the heat sink of each intake air fan is mounted with a thermal paste to a hot side of one of the plurality of thermoelectric modules, and
the heat sink of each outtake cooling fan is mounted with the thermal paste to a cold side of one of the plurality of thermoelectric modules.

12. The solar photovoltaic-powered thermoelectric system of claim 1, wherein the plurality of sensors include at least one temperature sensor, at least one relative humidity sensor and at least one solar radiation intensity sensor, wherein the measurement signals include temperature signals, relative humidity signals and solar radiation intensity signals respectively.

13. The solar photovoltaic-powered thermoelectric system of claim 12, further comprising:
a motor including a linear actuator attached to the sliding mechanism,
a load sensing program stored in the memory of the microcontroller, wherein the at least one processor is configured to execute the load sensing program based on the temperature signals, the relative humidity signals and the solar radiation intensity signals and generate drive signals which actuate the motor.

14. The solar photovoltaic-powered thermoelectric system of claim 1, further comprising a remote control mechanism configured to turn ON the microcontroller and generate drive signals which actuate a motor including a linear actuator attached to the sliding mechanism.

15. The solar photovoltaic-powered thermoelectric system of claim 1, further comprising:
an intake fan cover located over the intake fan opening, wherein the intake fan cover is configured with louvered vents; and
an outtake fan cover located over the outtake fan openings, wherein the outtake fan cover includes an outtake port configured to receive the air duct.

16. A method for using a solar photovoltaic-powered thermoelectric system to cool air, comprising:
turning ON the solar photovoltaic-powered thermoelectric system;
providing power from a rechargeable battery located in a lower section of a cabinet surrounding the solar photovoltaic-powered thermoelectric system to a plurality of intake air fans located within intake fan openings in a first wall of the cabinet, wherein the plurality of intake air fans are configured to draw ambient air into an upper section of the cabinet;
providing a DC current to a plurality of thermoelectric modules mounted on a panel located at a center of the cabinet, wherein the panel is configured to divide the upper section of the cabinet into a hot side and a cold side;
generating, by the DC current, a heated surface on each of the plurality of thermoelectric modules on the hot side and a cooled surface on each of the plurality of thermoelectric modules on the cold side;
providing the DC current to a plurality of outtake air fans located within outtake fan openings in a second wall of the cabinet, wherein the plurality of outtake air fans are configured to draw cooled air from the cold side and expel the cooled air through a duct covering the plurality of outtake fan openings;
generating, by a plurality of sensors, a plurality of measurement signals;
actuating, by a microcontroller including an electrical circuitry, a memory storing program instructions including a load sensing program, and at least one processor configured to execute the program instructions and analyze the plurality of measurement signals based on the load sensing program, a motor of a sliding mechanism connected to the exterior face of a top surface of the cabinet, wherein the sliding mechanism is connected by a linear actuator to a fixed bifacial photovoltaic panel, a first sliding bifacial photovoltaic panel and a second sliding bifacial photovoltaic panel located below the fixed photovoltaic module;
generating, during daylight hours, a DC electrical current with the fixed bifacial photovoltaic panel, the first sliding bifacial photovoltaic panel and the second sliding bifacial photovoltaic panel; and
recharging the rechargeable battery with the DC electrical current.

17. The method of claim 16, further comprising:
cleaning, by a plurality of self-cleaning brushes located on the sliding mechanism, a surface of the first sliding bifacial photovoltaic panel and a surface of the second sliding bifacial photovoltaic panel as the first sliding bifacial photovoltaic panel and the second sliding bifacial photovoltaic panel slide past the plurality of self-cleaning brushes.

18. The method of claim 16, further comprising:
generating the measurement signals by at least one temperature sensor, at least one relative humidity sensor and at least one solar radiation intensity sensor of the plurality of sensors.

19. The method of claim 16, wherein the microcontroller is operatively connected to the rechargeable battery, the plurality of intake cooling fans, the plurality of outtake cooling fans, the fixed bifacial photovoltaic panel, the first sliding bifacial photovoltaic panel, the second sliding bifacial photovoltaic panel, the plurality of thermoelectric modules, the plurality of sensors and the motor of the sliding mechanism, wherein the at least one processor is further configured to execute the program instructions for:
charging the rechargeable battery with the DC current generated by an inverter connected to the fixed bifacial photovoltaic module, the first sliding bifacial photovoltaic panel and the second sliding bifacial photovoltaic panel based on the load sensing program;
providing the current from the rechargeable battery to the plurality of thermoelectric modules;
actuating the plurality of intake cooling fans; and
actuating the plurality of outtake cooling fans.

20. The method of claim 16, further comprising:
turning ON the solar photovoltaic-powered thermoelectric system with a remote controller.
